(19) United States
(12) Patent Application Publication
(10) Pub. No.: US 2025/0183873 A1
(43) Pub. Date: Jun. 5, 2025

(54) PIEZOELECTRIC VIBRATION ELEMENT

(71) Applicant: Murata Manufacturing Co., Ltd., Nagaokakyo-shi (JP)

(72) Inventors: Daiki MURAUCHI, Nagaokakyo-shi (JP); Toshio NISHIMURA, Nagaokakyo-shi (JP)

(21) Appl. No.: 19/044,813

(22) Filed: Feb. 4, 2025

Related U.S. Application Data
(63) Continuation of application No. PCT/JP2024/013407, filed on Apr. 1, 2024.

(30) Foreign Application Priority Data
Jul. 19, 2023 (JP) 2023-117392

(51) Int. Cl. H03H 9/19; H10N 30/20; H10N 30/87

(52) U.S. Cl. CPC H03H 9/19; H10N 30/20; H10N 30/87

(57) ABSTRACT

A piezoelectric vibration element that includes: a piezoelectric substrate; a first excitation electrode on a first main surface of the piezoelectric substrate; a second excitation electrode on a second main surface of the piezoelectric substrate; and a mass-adding film at least a part of which overlaps with the first excitation electrode, the mass-adding film including a first part and a second part which do not overlap a central portion of the first excitation electrode, the first part extends along a first outer edge portion of the first excitation electrode and the second part extends along a second outer edge portion of the first excitation electrode so as to define a high acoustic velocity region, a first low acoustic velocity region, and a second low acoustic velocity region in a plan view.

### CROSS REFERENCE TO RELATED APPLICATIONS

The present application is a continuation of International application No. PCT/JP2024/013407, filed Apr. 1, 2024, which claims priority to Japanese Patent Application No. 2023-117392, filed Jul. 19, 2023, the entire contents of each of which are incorporated herein by reference.

### TECHNICAL FIELD

The present disclosure relates to a piezoelectric vibration element.

### BACKGROUND ART

In various electronic devices such as mobile communication terminals, communication base stations, and home appliances, piezoelectric vibration elements are used for applications of timing devices, sensors, oscillators, and the like. The piezoelectric vibration element includes a piezoelectric substrate having a pair of main surfaces, and a pair of excitation electrodes provided on the pair of main surfaces of the piezoelectric substrate.

For example, Patent Document 1 discloses a quartz crystal resonator including: a quartz crystal element having a first main surface and a second main surface; a first excitation electrode provided on the first main surface; and a second excitation electrode provided on the second main surface, in which the first excitation electrode and the second excitation electrode have a film thickness portion having a film thickness greater than that of other parts at an electrode end portion.
Patent Document 1: International Publication No. 2022/080426

### SUMMARY OF THE DISCLOSURE

However, in the quartz crystal resonator disclosed in Patent Document 1, the electromechanical coupling coefficient may deteriorate due to positional deviation of the film thickness portion caused by manufacturing variations.

The present disclosure has been made in view of such circumstances, and an object thereof is to provide a piezoelectric vibration element capable of suppressing deterioration in electromechanical coupling coefficient.

According to an aspect of the present disclosure, there is provided a piezoelectric vibration element that includes: a piezoelectric substrate having a first main surface that extends in a first direction and a second direction intersecting the first direction, and a second main surface facing the first main surface; a first excitation electrode on the first main surface of the piezoelectric substrate, wherein the first excitation electrode includes a first outer edge portion on a side in the first direction with respect to a central portion thereof and a second outer edge portion on a second side in the first direction with respect to the central portion, in a plan view of the piezoelectric vibration element; a second excitation electrode on the second main surface of the piezoelectric substrate, wherein the second excitation electrode includes a third outer edge portion on the first side in the first direction with respect to the central portion and a fourth outer edge portion on the second side in the first direction with respect to the central portion, in the plan view; and a mass-adding film at least a part of which overlaps with the first excitation electrode, wherein the mass-adding film includes a first part and a second part which do not overlap the central portion of the first excitation electrode, wherein the first part extends along the first outer edge portion, and the second part extends along the second outer edge portion, and when a first region where the piezoelectric substrate, the first excitation electrode, and the second excitation electrode overlap with each other is defined as a high acoustic velocity region, a second region where the piezoelectric substrate, the first excitation electrode, and the second excitation electrode overlap with the first part of the mass-adding film is defined as a first low acoustic velocity region, and a third region where the piezoelectric substrate, the first excitation electrode, and the second excitation electrode overlap with the second part of the mass-adding film is defined as a second low acoustic velocity region, in the plan view: the third outer edge portion is farther from the central portion than the first low acoustic velocity region, and the fourth outer edge portion is farther from the central portion than the second low acoustic velocity region.

According to another aspect of the present disclosure, there is provided a piezoelectric vibration element that includes: a piezoelectric substrate having a first main surface that extends in a first direction and a second direction intersecting the first direction, and a second main surface facing the first main surface; a first excitation electrode on the first main surface of the piezoelectric substrate, wherein the first excitation electrode includes a first outer edge portion on a side in the first direction with respect to a central portion thereof and a second outer edge portion on a second side in the first direction with respect to the central portion, in a plan view of the piezoelectric vibration element; a second excitation electrode on the second main surface of the piezoelectric substrate, wherein the second excitation electrode includes a third outer edge portion on the first side in the first direction with respect to the central portion and a fourth outer edge portion on the second side in the first direction with respect to the central portion, in the plan view; and a mass-adding film at least a part of which overlaps with the first excitation electrode, wherein the mass-adding film includes a first part and a second part which do not overlap the central portion of the first excitation electrode, wherein the first part extends along the first outer edge portion, and the second part extends along the second outer edge portion, and when a first region where the piezoelectric substrate, the first excitation electrode, and the second excitation electrode overlap with each other is defined as a high acoustic velocity region, a second region where the piezoelectric substrate, the first excitation electrode, and the second excitation electrode overlap with the first part of the mass-adding film is defined as a first low acoustic velocity region, and a third region where the piezoelectric substrate, the first excitation electrode, and the second excitation electrode overlap with the second part of the mass-adding film is defined as a second low acoustic velocity region, in the plan view: the third outer edge portion is farther from the central portion than the first low acoustic velocity region, and the fourth outer edge portion is farther from the central portion than the second low acoustic velocity region.

According to the present disclosure, it is possible to provide a piezoelectric vibration element capable of suppressing deterioration in electromechanical coupling coefficient.

### BRIEF DESCRIPTION OF THE DRAWINGS

FIG. 1 is a cross-sectional view of a crystal oscillator according to a first embodiment.

FIG. 2 is an exploded perspective view of a quartz crystal resonator unit according to the first embodiment.

FIG. 3 is a cross-sectional view of the quartz crystal resonator unit according to the first embodiment.

FIG. 4 is a cross-sectional view of a quartz crystal resonator according to the first embodiment.

FIG. 5 is a plan view of the quartz crystal resonator according to the first embodiment.

FIG. 6 is a table showing simulation conditions based on the first embodiment.

FIG. 7 is a graph showing simulation results based on the first embodiment.

FIG. 8 is a graph showing simulation results based on the first embodiment.

FIG. 9 is a graph showing simulation results based on the first embodiment.

FIG. 10 is a graph showing simulation results based on the first embodiment.

FIG. 11 is a graph showing simulation results based on the first embodiment.

FIG. 12 is a graph showing simulation results based on the first embodiment.

FIG. 13 is a graph showing simulation results based on the first embodiment.

FIG. 14 is a graph showing simulation results based on the first embodiment.

FIG. 15 is a graph showing simulation results based on the first embodiment.

FIG. 16 is a graph showing simulation results based on the first embodiment.

FIG. 17 is a view for describing the influence of positional deviation in the first embodiment.

FIG. 18 is a view for describing the influence of positional deviation in the first embodiment.

FIG. 19 is a cross-sectional view of a quartz crystal resonator according to a second embodiment.

FIG. 20 is a cross-sectional view of a quartz crystal resonator according to a third embodiment.

FIG. 21 is a cross-sectional view of a quartz crystal resonator according to a fourth embodiment.

FIG. 22 is a view for describing the influence of positional deviation in the fourth embodiment.

FIG. 23 is a view for describing the influence of positional deviation in the fourth embodiment.

FIG. 24 is a cross-sectional view of a quartz crystal resonator according to a fifth embodiment.

FIG. 25 is a view for describing the influence of positional deviation in the fifth embodiment.

FIG. 26 is a view for describing the influence of positional deviation in the fifth embodiment.

FIG. 27 is a cross-sectional view of a quartz crystal resonator according to a sixth embodiment.

FIG. 28 is a view for describing the influence of positional deviation in the sixth embodiment.

FIG. 29 is a view for describing the influence of positional deviation in the sixth embodiment.

FIG. 30 is a cross-sectional view of a quartz crystal resonator according to a seventh embodiment.

FIG. 31 is a cross-sectional view of a quartz crystal resonator according to an eighth embodiment.

FIG. 32 is a table showing simulation results of Comparative Example and Examples based on the first to eighth embodiments.

FIG. 33 is a table showing simulation conditions of Comparative Example and Examples based on the first to eighth embodiments.

FIG. 34 is a cross-sectional view of a quartz crystal resonator according to a ninth embodiment.

FIG. 35 is a plan view of a quartz crystal resonator according to a tenth embodiment.

FIG. 36 is a plan view of a quartz crystal resonator according to an eleventh embodiment.

### DETAILED DESCRIPTION OF THE PREFERRED EMBODIMENTS

Hereinafter, embodiments of the present disclosure will be described. In the following description of the drawings, the same or similar components are defined as the same or similar reference numerals. The drawings are examples, and a dimension and a shape of each portion are schematic. The technical scope of the present disclosure should not be interpreted as being limited to the embodiments. In the following description, “dimension” means a length of an object, and “distance” means a length of an interval between two objects.

Each drawing may be attached with an orthogonal coordinate system including an X axis, a Y′ axis, and a Z′ axis for convenience, in order to clarify a mutual relationship between the respective drawings and to help understanding of a positional relationship between respective members. The X axis, the Y′ axis, and the Z′ axis correspond to each other in each drawing. The X axis, the Y′ axis, and the Z′ axis correspond to crystallographic axes of a quartz crystal element 11, which will be described later. The X axis corresponds to an electric axis (polar axis) of the quartz crystal, the Y axis corresponds to a mechanical axis of the quartz crystal, and the Z axis corresponds to an optical axis of the quartz crystal. The Y′ axis and the Z′ axis are respectively axes obtained by rotating the Y axis and the Z axis around the X axis in a direction from the Y axis to the Z axis by 35 degrees 15 minutes #1 minute 30 seconds.

In the following description, a direction parallel to the X axis is referred to as an “X axis direction”, a direction parallel to the Y′ axis is referred to as a “Y′ axis direction”, and a direction parallel to the Z′ axis is referred to as a “Z′ axis direction”. In addition, a direction of an end of an arrow on the X axis, the Y′ axis, and the Z′ axis is referred to as “positive” or “+ (plus)”, and a direction opposite to the arrow is referred to as “negative” or “− (minus)”. For convenience, the description is made assuming that the +Y′ axis direction is the upward direction and the −Y′ axis direction is the downward direction, but the vertical direction of a quartz crystal resonator 10, a quartz crystal resonator unit 1, and a crystal oscillator 100 is not limited. In addition, a plane specified by the X axis and the Z′ axis is defined as a Z′X plane, and the same applies to a plane specified by other axes.

### First Embodiment

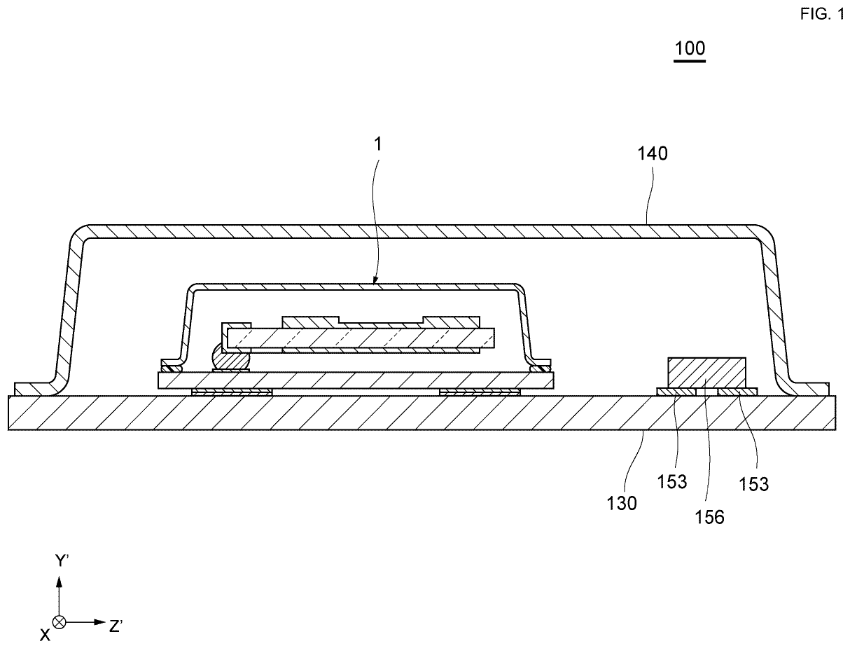

First, a schematic configuration of a crystal oscillator according to an embodiment will be described with reference to FIG. 1. FIG. 1 is a cross-sectional view of the crystal oscillator according to a first embodiment.

In the following description, as the piezoelectric oscillator, a crystal oscillator (XO) including a quartz crystal resonator unit is taken as an example. In addition, as a piezoelectric resonator unit, a quartz crystal resonator unit including a quartz crystal resonator will be taken as an example for description. In addition, as the piezoelectric vibration element, a quartz crystal resonator including a quartz crystal element will be described as an example. The quartz crystal element is a type of piezoelectric body (piezoelectric substrate) that vibrates according to an applied voltage. The piezoelectric oscillator is not limited to a quartz crystal resonator unit, and may be an oscillator using another piezoelectric body such as ceramic. Similarly, the piezoelectric resonator unit is not limited to a quartz crystal resonator unit, and may be a resonator unit using another piezoelectric body such as ceramic. In addition, similarly, the piezoelectric vibration element is not limited to a quartz crystal resonator, and may be an element using another piezoelectric body such as ceramic.

As illustrated in FIG. 1, the crystal oscillator 100 includes the quartz crystal resonator unit 1, a mounting substrate 130, a lid 140, and an electronic component 156.

The quartz crystal resonator unit 1 and the electronic component 156 are accommodated in a space formed between the mounting substrate 130 and the lid 140. The space formed by the mounting substrate 130 and the lid 140 is, for example, airtightly sealed. The space may be airtightly sealed in a vacuum state or may be airtightly sealed in a state of being filled with a gas such as an inert gas.

The mounting substrate 130 is a circuit board having a flat plate shape. The mounting substrate 130 includes, for example, a glass epoxy plate and a wiring layer patterned on the glass epoxy plate.

The quartz crystal resonator unit 1 is provided on one surface (an upper surface in FIG. 1) of the mounting substrate 130. More specifically, the quartz crystal resonator unit 1 is electrically coupled to the wiring layer of the mounting substrate 130 by solders 153.

The lid 140 includes a bottom cavity that is open on one side (a lower side in FIG. 1). In other words, the lid 140 includes a top wall portion having a flat plate shape, side wall portions that extend from an outer edge of the top wall portion toward the mounting substrate 130, and flange portions that extend from ends of the side wall portions to outer side portions. The flange portion is bonded to one surface (the upper surface in FIG. 1) of the mounting substrate 130. Thereby, the quartz crystal resonator unit 1 bonded to the mounting substrate 130 is accommodated in the lid 140. The lid 140 is formed of a metal material, and is formed, for example, by performing drawing on a metal sheet.

The electronic component 156 is provided on one surface (the upper surface in FIG. 1) of the mounting substrate 130. More specifically, the wiring layer of the mounting substrate 130 and the electronic component 156 are bonded by the solder 153. Thereby, the electronic component 156 is mounted on the mounting substrate 130.

The electronic component 156 is electrically coupled to the quartz crystal resonator unit 1 via the wiring layer of the mounting substrate 130. The electronic component 156 includes, for example, a capacitor, an IC chip, and the like. The electronic component 156 is, for example, a part of an oscillation circuit that oscillates the quartz crystal resonator unit 1, a part of a temperature compensation circuit that compensates for the temperature characteristics of the quartz crystal resonator unit 1, or the like. In a case where the electronic component 156 includes the temperature compensation circuit, the crystal oscillator 100 corresponds to an example of a temperature compensated crystal oscillator (TCXO). The crystal oscillator 100 may correspond to an example of a voltage controlled crystal oscillator (VCXO) or may correspond to an example of an oven controlled crystal oscillator (OCXO).

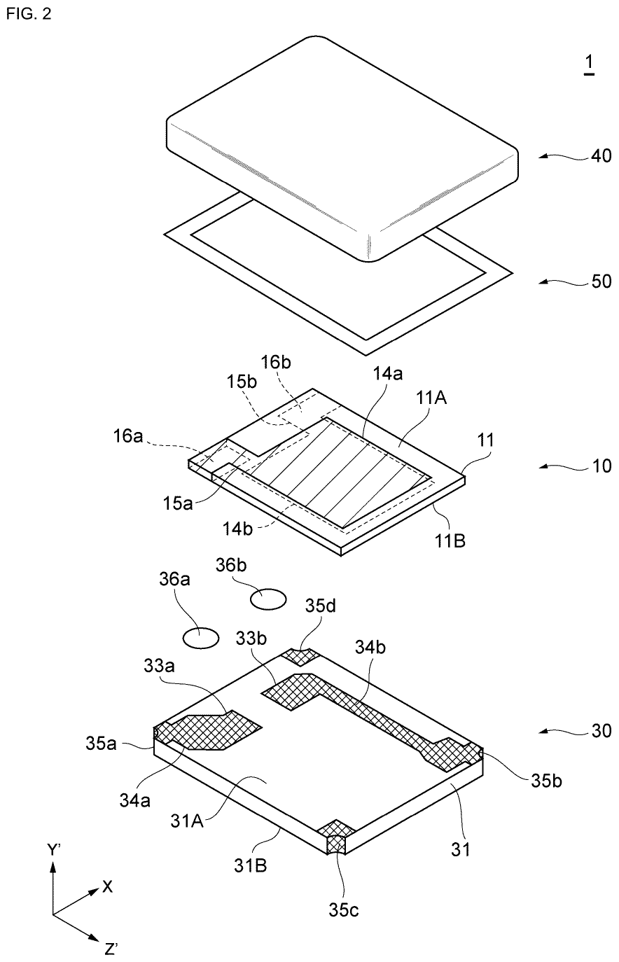

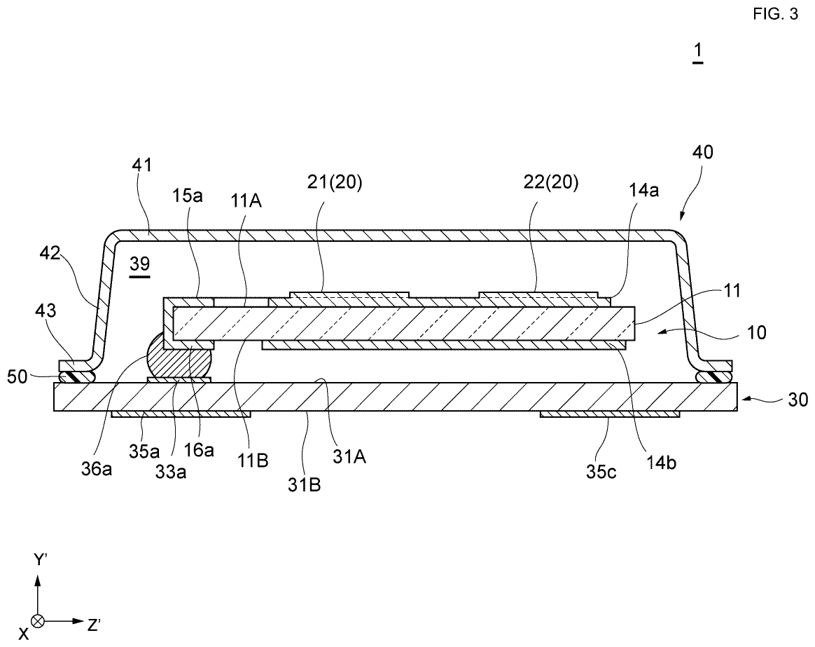

Next, a configuration of the quartz crystal resonator unit 1 according to the first embodiment will be described with reference to FIGS. 2 and 3. FIG. 2 is an exploded perspective view of the quartz crystal resonator unit according to the first embodiment. FIG. 3 is a cross-sectional view of the quartz crystal resonator unit according to the first embodiment.

The Z′ axis direction corresponds to an example of a “first direction”, the X axis direction corresponds to an example of a “second direction”, and the Y′ axis direction corresponds to an example of a “third direction”. The Y′ axis direction corresponds to an example of a “thickness direction”. Here, the first direction, the second direction, and the third direction are not limited to the directions described above. For example, the X axis direction may be the first direction, and the Z′ axis direction may be the second direction.

The quartz crystal resonator unit 1 includes the quartz crystal resonator 10, a base member 30, a lid member 40, and a bonding portion 50.

The quartz crystal resonator 10 is an electromechanical energy conversion element that mutually converts electric energy and mechanical energy by a piezoelectric effect. The frequency of the main mode of the quartz crystal resonator 10 is, for example, about 0.8 GHz to 2.0 GHz and is, for example, about 0.95 GHz. A frequency of an inharmonic mode of the quartz crystal resonator 10 is, for example, within a range of approximately 1% of the frequency of the main mode. The quartz crystal resonator 10 includes the quartz crystal element 11 having a flake shape, a first excitation electrode 14a and a second excitation electrode 14b constituting a pair of excitation electrodes, a first extended electrode 15a and a second extended electrode 15b constituting a pair of extended electrodes, a first coupling electrode 16a and a second coupling electrode 16b constituting a pair of coupling electrodes, and a mass-adding film 20.

The quartz crystal element 11 has an upper surface 11A and a lower surface 11B that face each other. The upper surface 11A is positioned on a side that faces a top wall portion 41 of the lid member 40. The lower surface 11B is positioned on a side that faces the base member 30. The upper surface 11A and the lower surface 11B correspond to a pair of main surfaces of the quartz crystal element 11.

The quartz crystal element 11 is, for example, an AT cut quartz crystal. The AT cut quartz crystal is formed such that the XZ′ plane is the main surface and the thickness is in a direction parallel to the Y′ axis. As an example, when the upper surface 11A is viewed in plan view in the thickness direction (hereinafter simply referred to as a “plan view”), a shape of the quartz crystal element 11 (hereinafter referred to as a “planar shape”) is a square shape having a pair of sides extending in the Z′ axis direction and a pair of sides extending in the X axis direction. Further, the quartz crystal element 11 has a thickness in the Y′ axis direction. As an example, the shape of the quartz crystal element 11 is a flat plate shape having a uniform thickness.

The planar shape of the quartz crystal element is not limited to the shape described above. For example, the planar shape of the quartz crystal element may be a rectangular shape having a long side extending in the Z′ axis direction and a short side extending in the X axis direction, and may be a rectangular shape having a short side extending in the Z′ axis direction and a long side extending in the X axis direction. The planar shape of the quartz crystal element may be a polygonal shape, a circular shape, an elliptical shape, or a shape obtained by combining these shapes. Further, the quartz crystal element is not limited to a flat plate shape. The quartz crystal element may have a mesa type structure or an inverted mesa type structure having unevenness on at least one of the upper surface 11A and the lower surface 11B. The quartz crystal element may have a convex structure in which an amount of change in the thickness changes continuously, or may have a bevel structure in which an amount of change in the thickness changes discontinuously.

The axes obtained by rotating the Y axis and the Z axis among the X axis, the Y axis, and the Z axis, which are crystallographic axes of a synthetic quartz crystal, by 35 degrees 15 minutes±1 minute 30 seconds in the direction from the Y axis to the Z axis around the X axis are defined as the Y′ axis and the Z′ axis, respectively, and the quartz crystal element 11 of an AT cut type is obtained by cutting out the XZ′ plane as a main surface.

The quartz crystal resonator 10 using the AT cut quartz crystal element 11 has high frequency stability in a wide temperature range. Further, the AT cut quartz crystal resonator also has excellent aging characteristics and can be manufactured at low cost. Further, the AT cut quartz crystal resonator uses a thickness shear vibration mode as a main vibration.

The cut-angles of the quartz crystal element are not limited to the angles described above. The rotation angles of the Y′ axis and the Z′ axis in the AT cut quartz crystal element 11 may be tilted in a range of −5 degrees to +15 degrees from 35 degrees 15 minutes. In addition, as the cut-angles of the quartz crystal element, a different cut other than the AT cut, for example, a BT cut, a GT cut, an SC cut, or the like may be applied. Further, the main vibration mode of the quartz crystal resonator is not limited to the thickness shear vibration mode, and may be, for example, a thickness longitudinal vibration, a spreading vibration, a length vibration, or a bending vibration.

The first excitation electrode 14a and the second excitation electrode 14b apply an alternating voltage to the quartz crystal element 11 to excite the quartz crystal element 11. The first excitation electrode 14a and the second excitation electrode 14b are provided at the central portion of the quartz crystal element 11 in plan view. The first excitation electrode 14a is provided on the upper surface 11A, and the second excitation electrode 14b is provided on the lower surface 11B. The first excitation electrode 14a and the second excitation electrode 14b face each other in the Y′ axis direction with the quartz crystal element 11 interposed therebetween. The first excitation electrode 14a corresponds to an example of an “excitation electrode”.

A planar shape of the first excitation electrode 14 is a rectangular shape having a short side that extends in the Z′ axis direction and a long side that extends in the X axis direction. Further, the first excitation electrode 14a has a thickness in the Y′ axis direction. The second excitation electrode 14b also has the same shape.

The planar shapes of the first excitation electrode and the second excitation electrode are not limited to the shape described above. The planar shapes of the first excitation electrode and the second excitation electrode may be a rectangular shape having a short side extending in the X axis direction. In addition, the planar shapes of the first excitation electrode and the second excitation electrode may be a square shape, a polygonal shape, a circular shape, an elliptical shape, or a combination thereof.

The first extended electrode 15a electrically couples the first excitation electrode 14a and the first coupling electrode 16a, and the second extended electrode 15b electrically couples the second excitation electrode 14b and the second coupling electrode 16b. The first extended electrode 15a is provided from the upper surface 11A to the lower surface 11B of the quartz crystal element 11, and the second extended electrode 15b is provided on the lower surface 11B of the quartz crystal element 11.

The first coupling electrode 16a and the second coupling electrode 16b electrically couple the quartz crystal resonator 10 to the base member 30. The first coupling electrode 16a and the second coupling electrode 16b are provided on the lower surface 11B of the quartz crystal element 11.

The first excitation electrode 14a, the first extended electrode 15a, and the first coupling electrode 16a are integrally provided. The same applies to the second excitation electrode 14b, the second extended electrode 15b, and the second coupling electrode 16b. The electrodes of the quartz crystal resonator 10 have, for example, a multi-layer structure provided by laminating a base layer and a surface layer in this order. For example, the base layer is a chromium (Cr) layer having good adhesive properties to the quartz crystal element 11, and the surface layer is a gold (Au) layer having good chemical stability. The electrode of the quartz crystal resonator 10 may contain titanium (Ti), aluminum (Al), molybdenum (Mo), or an aluminum-copper alloy (AlCu) containing aluminum (Al) as a main component. The electrodes of the quartz crystal resonator 10 may have a single layer structure.

The mass-adding film 20 reduces a part of the acoustic velocity in a region in which the first excitation electrode 14a and the second excitation electrode 14b face each other due to the mass addition effect. The mass-adding film 20 is provided on a side of the first excitation electrode 14a opposite to the quartz crystal element 11. At least a part of the mass-adding film 20 overlaps with the first excitation electrode 14a. The material of the mass-adding film 20 is an electric conductor and is, for example, the same as the material of the first excitation electrode 14a.

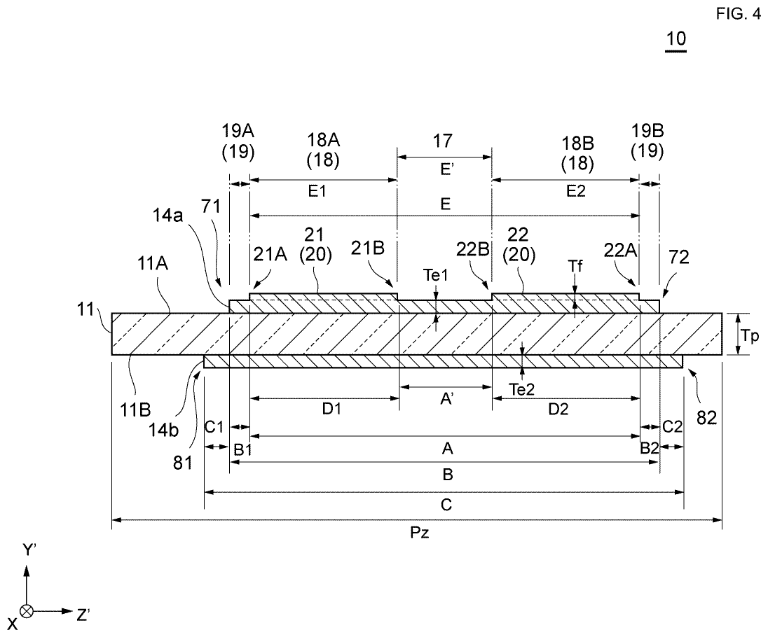

In a case where the materials of the first excitation electrode 14a and the mass-adding film 20 are the same and the boundary therebetween is unclear, a part positioned on the opposite side of the quartz crystal element 11 with respect to the XZ′ plane including the surface of the first excitation electrode 14a in the high acoustic velocity region 17 (refer to FIG. 4) is defined as the mass-adding film 20.

The mass-adding film may be provided on a side of the second excitation electrode opposite to the crystal substrate 11 instead of on a side of the first excitation electrode opposite to the quartz crystal element. The material of the mass-adding film 20 may be a metal different from the first excitation electrode or may be an insulator.

The base member 30 holds the quartz crystal resonator 10 such that the quartz crystal resonator 10 is excited. The base member 30 includes a base 31, coupling electrodes 33a and 33b, extended electrodes 34a and 34b, outer electrodes 35a, 35b, 35c, and 35d, and conductive holding members 36a and 36b.

The base 31 is a plate-shaped insulator having an upper surface 31A and a lower surface 31B that face each other in the thickness direction. The upper surface 31A and the lower surface 31B correspond to a pair of main surfaces of the base 31. The upper surface 31A is positioned on a side facing the quartz crystal resonator 10 and the lid member 40 and corresponds to a mounting surface on which the quartz crystal resonator 10 is mounted. From the viewpoint of suppressing a thermal stress acting on the quartz crystal resonator 10 from the base 31 due to thermal history such as reflow, the base 31 is preferably formed of a heat-resistant material. From the same viewpoint, the base 31 may be formed of a material having a thermal expansion coefficient close to that of the quartz crystal element 11. The base 31 is formed of, for example, a ceramic substrate, a glass substrate, or a quartz crystal substrate.

A corner portion of the base 31 has a notched side surface of which a part is formed in a cylindrically curved surface shape (also referred to as a castellation shape). The shape of the corner portion of the base 31 is not limited thereto. The corner portion of the base may have a notched side surface formed in a prism shape, or may be a substantially right-angled corner portion without a notch.

The coupling electrodes 33a and 33b are electrically coupled to the quartz crystal resonator 10. The coupling electrode 33a is electrically coupled to the coupling electrode 16a of the quartz crystal resonator 10, and the coupling electrode 33b is coupled to the coupling electrode 16b of the quartz crystal resonator 10.

The extended electrode 34a electrically couples the coupling electrode 33a and the outer electrode 35a, and the extended electrode 34b electrically couples the coupling electrode 33b and the outer electrode 35b. The extended electrodes 34a and 34b are provided on the upper surface 31A of the base 31.

The outer electrodes 35a and 35b are external terminals for electrically coupling the quartz crystal resonator 10 to an external substrate. The outer electrode 35a electrically couples the first excitation electrode 14a of the quartz crystal resonator 10 to the mounting substrate 130, and the outer electrode 35b electrically couples the second excitation electrode 14b of the quartz crystal resonator 10 to the mounting substrate 130. One electrode of the outer electrodes 35c and 35d is a ground electrode that grounds the lid member 40, and the other electrode of the outer electrodes 35c and 35d is a dummy electrode that is not electrically coupled to the quartz crystal resonator 10 or the lid member 40. Each of the outer electrodes 35a, 35b, 35c, and 35d is continuously provided from the notched side surfaces provided at the four corner portions of the base 31 to the lower surface 31B. In the example illustrated in FIG. 2, the outer electrode 35a and the outer electrode 35b are positioned at a diagonal angle on the upper surface 31A of the base 31, and the outer electrode 35c and the outer electrode 35d are positioned at the other diagonal angle on the upper surface 31A of the base 31. Here, the outer electrodes 35a, 35b, 35c, and 35d are not limited thereto. Both the outer electrodes 35c and 35d may be ground electrodes, or may be dummy electrodes. The outer electrodes 35c and 35d may be omitted. The outer electrode 35c may be electrically coupled to one electrode of the outer electrodes 35a and 35b, and the outer electrode 35d may be electrically coupled to the other electrode of the outer electrodes 35a and 35b.

The conductive holding members 36a and 36b electrically couple the base member 30 and the quartz crystal resonator 10 and mechanically hold the quartz crystal resonator 10. The conductive holding member 36a electrically couples the first coupling electrode 16a of the quartz crystal resonator 10 to the coupling electrode 33a of the base member 30. The conductive holding member 36b electrically couples the second coupling electrode 16b of the quartz crystal resonator 10 to the coupling electrode 33b of the base member 30. The conductive holding members 36a and 36b are cured products of a conductive adhesive including a thermosetting resin, a photocurable resin, or the like. The main component of the conductive holding members 36a and 36b is, for example, a silicone resin. The conductive holding members 36a and 36b include conductive particles, and as the conductive particles, for example, metal particles including silver (Ag) are used.

The main component of the conductive holding members 36a and 36b is not limited to a silicone resin, and may be, for example, an epoxy resin or an acrylic resin. In addition, the conductive particles included in the conductive holding members 36a and 36b are not limited to silver particles, and may be formed of other metals, conductive ceramics, conductive organic materials, and the like. The conductive holding members 36a and 36b may include a conductive polymer.

The lid member 40 forms an internal space 39 in which the quartz crystal resonator 10 is accommodated between the lid member 40 and the base member 30. The lid member 40 includes the top wall portion 41, side wall portions 42 that extend from the outer edge portion of the top wall portion 41 toward the base member 30, and flange portions 43 that extend from the end of the mounting substrate 130 to outer side portions. The top wall portion 41 faces the base member 30 with the quartz crystal resonator 10 interposed therebetween in the Y′ axis direction. The side wall portions 42 surround the quartz crystal resonator 10 at an interval in the XZ′ plane direction. The flange portions 43 are provided in a frame shape in plan view and are provided to be the closest to the base member 30 among the members forming the lid member 40. A material of the lid member 40 is preferably a conductive material, and more preferably a metal material having high airtightness. Since the lid member 40 is formed of a conductive material, the lid member 40 has an electromagnetic shield function of reducing electromagnetic waves entering and exiting the internal space 39. From the viewpoint of suppressing generation of a thermal stress, preferably, the material of the lid member 40 is a material having a thermal expansion coefficient close to that of the base member 30, and is, for example, an Fe—Ni—Co alloy of which the thermal expansion coefficient near normal temperature matches that of glass or ceramic over a wide temperature range. The lid member 40 is electrically coupled to at least one of the outer electrodes 35c and 35d by a ground member (not illustrated).

The bonding portion 50 bonds the base member 30 and the lid member 40 to seal the internal space 39. The bonding portion 50 is provided in a frame shape along the entire periphery of the flange portion 43 on the base member 30, and is sandwiched between the lower surface of the flange portion 43 of the lid member 40 and the upper surface 31A of the base member 30. The bonding portion 50 is formed of an insulating material. The bonding portion 50 is formed of, for example, an organic adhesive including an epoxy-based resin, a vinyl-based resin, an acrylic-based resin, an urethane-based resin, or a silicone resin. The material of the bonding portion 50 is not limited to an organic adhesive, and the bonding portion 50 may be formed of an inorganic adhesive such as a silicon-based adhesive including water glass or a calcium-based adhesive including cement. The material of the bonding portion 50 may be glass having a low melting point (for example, lead-boric-acid-based glass, tin-phosphate-based glass, or the like).

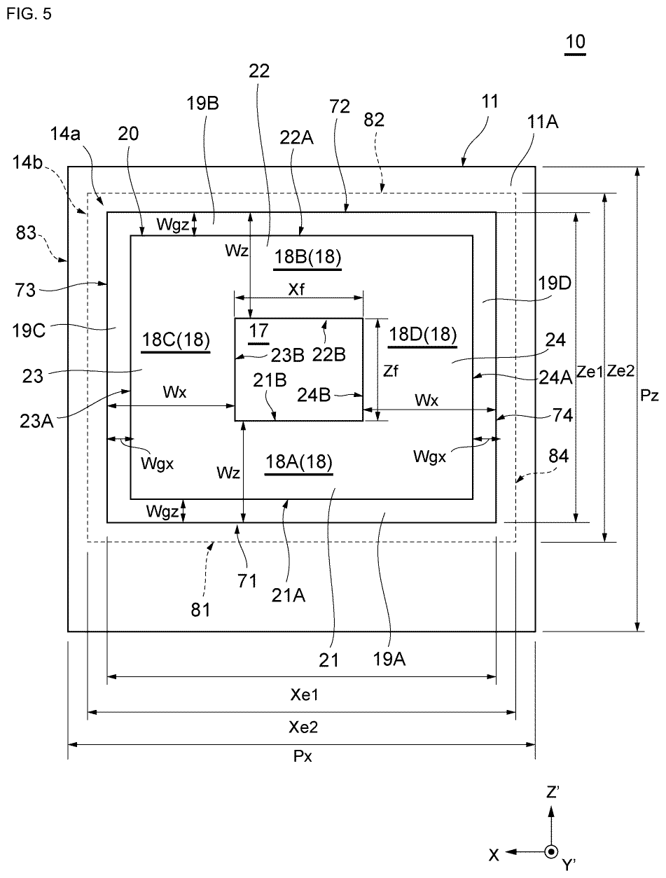

Next, the configuration of the quartz crystal resonator 10 according to the first embodiment will be described with reference to FIG. 4 and FIG. 5. FIG. 4 is a cross-sectional view of the quartz crystal resonator according to the first embodiment. FIG. 5 is a plan view of the quartz crystal resonator according to the first embodiment. For simplification of the description, in FIG. 4 and FIG. 5, the first extended electrode 15a, the second extended electrode 15b, the first coupling electrode 16a, and the second coupling electrode 16b are omitted.

The quartz crystal resonator 10 has a high acoustic velocity region 17, a low acoustic velocity region 18, and an outer high acoustic velocity region 19 in an excitation region where a voltage is applied and the quartz crystal resonator 10 is excited. The low acoustic velocity region 18 is a region in which the acoustic velocity is decreased due to a mass addition effect by providing the mass-adding film 20. The acoustic velocities of the high acoustic velocity region 17 and the outer high acoustic velocity region 19 are higher than the acoustic velocity of the low acoustic velocity region 18. The acoustic velocity in the high acoustic velocity region 17 is substantially the same as the acoustic velocity in the outer high acoustic velocity region 19.

As illustrated in FIG. 5, in plan view, the high acoustic velocity region 17 is provided in a region that overlaps with the central portion of the first excitation electrode 14a. The planar shape of the high acoustic velocity region 17 is a rectangular shape having a long side extending in the X axis direction and a short side extending in the Z′ axis direction.

The planar shape of the high acoustic velocity region is not limited to the shape described above. The planar shape of the high acoustic velocity region may be a rectangular shape having a short side extending in the X axis direction and a long side extending in the Z′ axis direction. Further, the planar shape of the high acoustic velocity region may be a square shape, a polygonal shape, a circular shape, an elliptical shape, or a combination thereof.

As shown in FIG. 5, in plan view, the low acoustic velocity region 18 is provided along the outer edge portion of the first excitation electrode 14a in a region inside the outer edge portion of the first excitation electrode 14a. The low acoustic velocity region 18 is provided in a frame shape surrounding a central portion of the first excitation electrode 14a. The low acoustic velocity region 18 has a first low acoustic velocity region 18A, a second low acoustic velocity region 18B, a third low acoustic velocity region 18C, and a fourth low acoustic velocity region 18D.

The first low acoustic velocity region 18A is adjacent to the high acoustic velocity region 17 on the negative Z′ axis direction side and extends in the X axis direction. The second low acoustic velocity region 18B is adjacent to the high acoustic velocity region 17 on the positive Z′ axis direction side and extends in the X axis direction. The third low acoustic velocity region 18C is adjacent to the high acoustic velocity region 17 on the positive X axis direction side and extends in the Z′ axis direction. The fourth low acoustic velocity region 18D is adjacent to the high acoustic velocity region 17 on the negative X axis direction side and extends in the Z′ axis direction. An end portion of the first low acoustic velocity region 18A on the positive X axis direction side is coupled to an end portion of the third low acoustic velocity region 18C on the negative Z′ axis direction side, and an end portion of the first low acoustic velocity region 18A on the negative X axis direction side is coupled to an end portion of the fourth low acoustic velocity region 18D on the negative Z′ axis direction side. An end portion of the second low acoustic velocity region 18B on the positive X axis direction side is coupled to an end portion of the third low acoustic velocity region 18C on the positive Z′ axis direction side, and an end portion of the second low acoustic velocity region 18B on the negative X axis direction side is coupled to an end portion of the fourth low acoustic velocity region 18D on the positive Z′ axis direction side.

In plan view, the end portion of the first low acoustic velocity region 18A on the positive X axis direction side overlaps with the end portion of the third low acoustic velocity region 18C on the negative Z′ axis direction side, and the end portion of the first low acoustic velocity region 18A on the negative X axis direction side overlaps with the end portion of the fourth low acoustic velocity region 18D on the negative Z′ axis direction side. The end portion of the second low acoustic velocity region 18B on the positive X axis direction side overlaps with the end portion of the third low acoustic velocity region 18C on the positive Z′ axis direction side, and the end portion of the second low acoustic velocity region 18B on the negative X axis direction side overlaps with the end portion of the fourth low acoustic velocity region 18D on the positive Z′ axis direction side.

In plan view, an outer edge portion positioned opposite to the central portion of the first excitation electrode 14a in the first low acoustic velocity region 18A overlaps with an outer edge portion (outer edge portion 21A which will be described later) positioned opposite to the central portion of the first excitation electrode 14a in a first part 21 (which will be described later) in the mass-adding film 20. An outer edge portion positioned opposite to the central portion of the first excitation electrode 14a in the second low acoustic velocity region 18B overlaps with an outer edge portion (outer edge portion 22A which will be described later) positioned opposite to the central portion of the first excitation electrode 14a in a second part 22 (which will be described later) in the mass-adding film 20. An outer edge portion positioned opposite to the central portion of the first excitation electrode 14a in the third low acoustic velocity region 18C overlaps with an outer edge portion (outer edge portion 23A which will be described later) positioned opposite to the central portion of the first excitation electrode 14a in a third part 23 (which will be described later) in the mass-adding film 20. An outer edge portion positioned opposite to the central portion of the first excitation electrode 14a in the fourth low acoustic velocity region 18D overlaps with an outer edge portion (outer edge portion 24A which will be described later) positioned opposite to the central portion of the first excitation electrode 14a in a fourth part 24 (which will be described later) in the mass-adding film 20.

In plan view, an inner edge portion positioned on the central portion side of the first excitation electrode 14a in the first low acoustic velocity region 18A overlaps with an inner edge portion (inner edge portion 21B which will be described later) positioned on the central portion side of the first excitation electrode 14a in the first part 21 (which will be described later) in the mass-adding film 20. An inner edge portion positioned on the central portion side of the first excitation electrode 14a in the second low acoustic velocity region 18B overlaps with an inner edge portion (inner edge portion 22B which will be described later) positioned on the central portion side of the first excitation electrode 14a in the second part 22 (which will be described later) in the mass-adding film 20. An inner edge portion positioned on the central portion side of the first excitation electrode 14a in the third low acoustic velocity region 18C overlaps with an inner edge portion (inner edge portion 23B which will be described later) positioned on the central portion side of the first excitation electrode 14a in the third part 23 (which will be described later) in the mass-adding film 20. An inner edge portion positioned on the central portion side of the first excitation electrode 14a in the fourth low acoustic velocity region 18D overlaps with an inner edge portion (inner edge portion 24B which will be described later) positioned on the central portion side of the first excitation electrode 14a in the fourth part 24 (which will be described later) in the mass-adding film 20.

In plan view, both an outer edge portion 71 (which will be described later) of the first excitation electrode 14a and an outer edge portion 81 (which will be described later) of the second excitation electrode 14b are farther from the central portion of the first excitation electrode 14a than the outer edge portion of the first low acoustic velocity region 18A. The outer edge portion 81 is farther from the central portion of the first excitation electrode 14a than the outer edge portion 71. Both an outer edge portion 72 (which will be described later) of the first excitation electrode 14a and an outer edge portion 82 (which will be described later) of the second excitation electrode 14b are farther from the central portion of the first excitation electrode 14a than the outer edge portion of the second low acoustic velocity region 18B. The outer edge portion 82 is farther from the central portion of the first excitation electrode 14a than the outer edge portion 72. Both an outer edge portion 73 (which will be described later) of the first excitation electrode 14a and an outer edge portion 83 (which will be described later) of the second excitation electrode 14b are farther from the central portion of the first excitation electrode 14a than the outer edge portion of the third low acoustic velocity region 18C. The outer edge portion 83 is farther from the central portion of the first excitation electrode 14a than the outer edge portion 73. Both an outer edge portion 74 (which will be described later) of the first excitation electrode 14a and an outer edge portion 84 (which will be described later) of the second excitation electrode 14b are farther from the central portion of the first excitation electrode 14a than the outer edge portion of the fourth low acoustic velocity region 18D. The outer edge portion 84 is farther from the central portion of the first excitation electrode 14a than the outer edge portion 74.

The shape of the low acoustic velocity region is not limited to the configuration described above. The third low acoustic velocity region and the fourth low acoustic velocity region may be omitted. That is, the high acoustic velocity region, the first low acoustic velocity region, and the second low acoustic velocity region may be provided in a strip shape extending in parallel with each other in the X axis direction. In addition, the first low acoustic velocity region and the second low acoustic velocity region may be omitted, and the high acoustic velocity region, the third low acoustic velocity region, and the fourth low acoustic velocity region may be provided in a strip shape extending in parallel with each other in the Z′ axis direction. Further, the end portion of the first low acoustic velocity region on the positive X axis direction side may be separated from the third low acoustic velocity region, and the end portion of the first low acoustic velocity region on the negative X axis direction side may be separated from the fourth low acoustic velocity region. The end portion of the second low acoustic velocity region on the positive X axis direction side may be separated from the third low acoustic velocity region, and the end portion of the second low acoustic velocity region on the negative X axis direction side may be separated from the fourth low acoustic velocity region.

Further, the positional relationship between the first low acoustic velocity region, the second low acoustic velocity region, the third low acoustic velocity region, and the fourth low acoustic velocity region is not limited to the relationship described above. The first low acoustic velocity region may be adjacent to the high acoustic velocity region on the positive Z′ axis direction side, and the second low acoustic velocity region may be adjacent to the high acoustic velocity region on the negative Z′ axis direction side. The third low acoustic velocity region may be adjacent to the high acoustic velocity region on the negative X axis direction side, and the fourth low acoustic velocity region may be adjacent to the high acoustic velocity region on the positive X axis direction side. One of the first low acoustic velocity region and the second low acoustic velocity region may be adjacent to the high acoustic velocity region on the negative X axis direction side, and the other one may be adjacent to the high acoustic velocity region on the positive X axis direction side. One of the third low acoustic velocity region and the fourth low acoustic velocity region may be adjacent to the high acoustic velocity region on the negative Z′ axis direction side, and the other one may be adjacent to the high acoustic velocity region on the positive Z′ axis direction side.

As shown in FIG. 5, in plan view, the outer high acoustic velocity region 19 is provided along the outer edge portion of the first excitation electrode 14a in a region between the outer edge portion of the mass-adding film 20 and the outer edge portion of the first excitation electrode 14a. The outer high acoustic velocity region 19 is provided in a frame shape surrounding the low acoustic velocity region 18. The outer high acoustic velocity region 19 includes a first outer high acoustic velocity region 19A, a second outer high acoustic velocity region 19B, a third outer high acoustic velocity region 19C, and a fourth outer high acoustic velocity region 19D.

The first outer high acoustic velocity region 19A is adjacent to the first low acoustic velocity region 18A on the negative Z′ axis direction side and extends in the X axis direction. The second outer high acoustic velocity region 19B is adjacent to the second low acoustic velocity region 18B on the positive Z′ axis direction side and extends in the X axis direction. The third outer high acoustic velocity region 19C is adjacent to the third low acoustic velocity region 18C on the positive X axis direction side and extends in the Z′ axis direction. The fourth outer high acoustic velocity region 19D is adjacent to the fourth low acoustic velocity region 18D on the negative X axis direction side and extends in the Z′ axis direction. An end portion of the first outer high acoustic velocity region 19A on the positive X axis direction side is coupled to an end portion of the third outer high acoustic velocity region 19C on the negative Z′ axis direction side, and an end portion of the first outer high acoustic velocity region 19A on the negative X axis direction side is coupled to an end portion of the fourth outer high acoustic velocity region 19D on the negative Z′ axis direction side. An end portion of the second outer high acoustic velocity region 19B on the positive X axis direction side is coupled to an end portion of the third outer high acoustic velocity region 19C on the positive Z′ axis direction side, and an end portion of the second outer high acoustic velocity region 19B on the negative X axis direction side is coupled to an end portion of the fourth outer high acoustic velocity region 19D on the positive Z′ axis direction side.

In plan view, the end portion of the first outer high acoustic velocity region 19A on the positive X axis direction side overlaps with the end portion of the third outer high acoustic velocity region 19C on the negative Z′ axis direction side, and the end portion of the first outer high acoustic velocity region 19A on the negative X axis direction side overlaps with the end portion of the fourth outer high acoustic velocity region 19D on the negative Z′ axis direction side. The end portion of the second outer high acoustic velocity region 19B on the positive X axis direction side overlaps with the end portion of the third outer high acoustic velocity region 19C on the positive Z′ axis direction side, and the end portion of the second outer high acoustic velocity region 19B on the negative X axis direction side overlaps with the end portion of the fourth outer high acoustic velocity region 19D on the positive Z′ axis direction side.

The shape of the outer high acoustic velocity region is not limited to the shape described above. The third outer high acoustic velocity region and the fourth outer high acoustic velocity region may be omitted. That is, the first outer high acoustic velocity region and the second outer high acoustic velocity region may be provided in a strip shape extending in parallel with each other in the X axis direction. At this time, the first outer high acoustic velocity region and the second outer high acoustic velocity region may be provided from the end portion on the negative X axis direction side to the end portion on the positive X axis direction side in the first excitation electrode in plan view. In addition, the first outer high acoustic velocity region and the second outer high acoustic velocity region may be omitted, and the third outer high acoustic velocity region and the fourth outer high acoustic velocity region may be provided in a strip shape extending in parallel with each other in the Z′ axis direction. In this case, the third outer high acoustic velocity region and the fourth outer high acoustic velocity region may be provided from the end portion on the negative Z′ axis direction side to the end portion on the positive Z′ axis direction side in the first excitation electrode in plan view. In addition, the first outer high acoustic velocity region may be separated from the third outer high acoustic velocity region or may be separated from the fourth outer high acoustic velocity region. The second outer high acoustic velocity region may be separated from the third outer high acoustic velocity region or may be separated from the fourth outer high acoustic velocity region.

The quartz crystal element 11, the first excitation electrode 14a, and the second excitation electrode 14b are provided in the high acoustic velocity region 17, the low acoustic velocity region 18, and the outer high acoustic velocity region 19. The mass-adding film 20 is further provided in the low acoustic velocity region 18. The mass-adding film 20 does not overlap the high acoustic velocity region 17 and the outer high acoustic velocity region 19. That is, the planar shape of the mass-adding film 20 is a frame shape that overlaps with the low acoustic velocity region 18.

The first excitation electrode 14a has the outer edge portions 71, 72, 73, and 74. The outer edge portion 71 is an edge portion of one side among the edge portions of the four sides of the first excitation electrode 14a in plan view, the one side extending along the X axis on the negative Z′ axis direction side. The outer edge portion 72 is an edge portion of one side extending along the X axis on the positive Z′ axis direction side, the outer edge portion 73 is an edge portion of one side extending along the Z′ axis on the positive X axis direction side, and the outer edge portion 74 is an edge portion of one side extending along the Z′ axis on the negative X axis direction side.

The second excitation electrode 14b has the outer edge portions 81, 82, 83, and 84. The outer edge portion 81 is an edge portion of one side among the edge portions of the four sides of the second excitation electrode 14b in plan view, the one side extending along the X axis on the negative Z′ axis direction side. The outer edge portion 82 is an edge portion of one side extending along the X axis on the positive Z′ axis direction side, the outer edge portion 83 is an edge portion of one side extending along the Z′ axis on the positive X axis direction side, and the outer edge portion 84 is an edge portion of one side extending along the Z′ axis on the negative X axis direction side.

The mass-adding film 20 includes the first part 21, the second part 22, the third part 23, and the fourth part 24. The first part 21 is provided on the first excitation electrode 14a in the first low acoustic velocity region 18A. The second part 22 is provided on the first excitation electrode 14a in the second low acoustic velocity region 18B. The third part 23 is provided on the first excitation electrode 14a in the third low acoustic velocity region 18C. The fourth part 24 is provided on the first excitation electrode 14a in the fourth low acoustic velocity region 18D.

The first part 21 is provided along the outer edge portion 71 of the first excitation electrode 14a positioned on the negative Z′ axis direction side of the high acoustic velocity region 17 and does not overlap the high acoustic velocity region 17. The second part 22 is provided along the outer edge portion 72 of the first excitation electrode 14a positioned on the positive Z′ axis direction side of the high acoustic velocity region 17 and does not overlap the high acoustic velocity region 17. The third part 23 is provided along the outer edge portion 73 of the first excitation electrode 14a positioned on the positive X axis direction side of the high acoustic velocity region 17 and does not overlap the high acoustic velocity region 17. The fourth part 24 is provided along the outer edge portion 74 of the first excitation electrode 14a positioned on the negative X axis direction side of the high acoustic velocity region 17 and does not overlap the high acoustic velocity region 17. In plan view, the first part 21 is separated from the outer edge portion 71, the second part 22 is separated from the outer edge portion 72, the third part 23 is separated from the outer edge portion 73, and the fourth part 24 is separated from the outer edge portion 74.

The first part 21 has the outer edge portion 21A positioned on the side of the outer high acoustic velocity region 19 and the inner edge portion 21B positioned on the side of the high acoustic velocity region 17. The second part 22 has the outer edge portion 22A positioned on the side of the outer high acoustic velocity region 19 and the inner edge portion 22B positioned on the side of the high acoustic velocity region 17. The third part 23 has the outer edge portion 23A positioned on the side of the outer high acoustic velocity region 19 and the inner edge portion 23B positioned on the side of the high acoustic velocity region 17. The fourth part 24 has the outer edge portion 24A positioned on the side of the outer high acoustic velocity region 19 and the inner edge portion 24B positioned on the side of the high acoustic velocity region 17.

The outer edge portions 21A, 22A, 23A, and 24A are positioned at a boundary between the low acoustic velocity region 18 and the outer high acoustic velocity region 19. The inner edge portions 21B, 22B, 23B, and 24B are positioned at a boundary between the high acoustic velocity region 17 and the low acoustic velocity region 18. The end portion of the outer edge portion 21A on the positive X axis direction side is coupled to the end portion of the outer edge portion 23A on the negative Z′ axis direction side, and the end portion of the outer edge portion 21A on the negative X axis direction side is coupled to the end portion of the outer edge portion 24A on the negative Z′ axis direction side. The end portion of the outer edge portion 22A on the positive X axis direction side is coupled to the end portion of the outer edge portion 23A on the positive Z′ axis direction side, and the end portion of the outer edge portion 22A on the negative X axis direction side is coupled to the end portion of the outer edge portion 24A on the positive Z′ axis direction side. The end portion of the inner edge portion 21B on the positive X axis direction side is coupled to the end portion of the inner edge portion 23B on the negative Z′ axis direction side, and the end portion of the inner edge portion 21B on the negative X axis direction side is coupled to the end portion of the inner edge portion 24B on the negative Z′ axis direction side. The end portion of the inner edge portion 22B on the positive X axis direction side is coupled to the end portion of the inner edge portion 23B on the positive Z′ axis direction side, and the end portion of the inner edge portion 22B on the negative X axis direction side is coupled to the end portion of the inner edge portion 24B on the positive Z′ axis direction side.

As shown in FIG. 5, in plan view, the outer edge portions 71 and 72 of the first excitation electrode 14a overlap with the second excitation electrode 14b. The outer edge portions 71 and 72 of the first excitation electrode 14a are positioned between the outer edge portion 81 and the outer edge portion 82 of the second excitation electrode 14b. The outer edge portion 71 of the first excitation electrode 14a is positioned between the outer edge portion 81 of the second excitation electrode 14b and the outer edge portion 21A of the first part 21 of the mass-adding film 20. The outer edge portion 72 of the first excitation electrode 14a is positioned between the outer edge portion 82 of the second excitation electrode 14b and the outer edge portion 22A of the second part 22 of the mass-adding film 20. Similarly, the outer edge portions 73 and 74 of the first excitation electrode 14a overlap with the second excitation electrode 14b. The outer edge portions 73 and 74 of the first excitation electrode 14a are positioned between the outer edge portions 83 and 84 of the second excitation electrode 14b. The outer edge portion 73 of the first excitation electrode 14a is positioned between the outer edge portion 83 of the second excitation electrode 14b and the outer edge portion 23A of the third part 23 of the mass-adding film 20. The outer edge portion 74 of the first excitation electrode 14a is positioned between the outer edge portion 84 of the second excitation electrode 14b and the outer edge portion 24A of the fourth part 24 of the mass-adding film 20.

As shown in FIG. 4, a distance between the outer edge portion 21A of the first part 21 and an outer edge portion 22A of the second part 22 in the mass-adding film 20 in the Z′ axis direction is defined as a length A. A distance between the inner edge portion 21B of the first part 21 and the inner edge portion 22B of the second part 22 in the mass-adding film 20 in the Z′ axis direction is defined as a length A′. A distance between the outer edge portion 71 and the outer edge portion 72 in the first excitation electrode 14a in the Z′ axis direction is defined as a length B. A distance between the outer edge portion 21A of the first part 21 in the mass-adding film 20 and the outer edge portion 71 of the first excitation electrode 14a in the Z′ axis direction is defined as a length B1. A distance between the outer edge portion 22A of the second part 22 in the mass-adding film 20 and the outer edge portion 72 of the first excitation electrode 14a in the Z′ axis direction is defined as a length B2. A distance between the outer edge portion 81 and the outer edge portion 82 in the second excitation electrode 14b in the Z′ axis direction is defined as a length C. A distance between the outer edge portion 71 of the first excitation electrode 14a and the outer edge portion 81 of the second excitation electrode 14b in the Z′ axis direction is set as a length C1. A distance between the outer edge portion 72 of the first excitation electrode 14a and the outer edge portion 82 of the second excitation electrode 14b in the Z′ axis direction is defined as a length C2. A distance between the outer edge portion 21A and the inner edge portion 21B of the first part 21 in the mass-adding film 20 in the Z′ axis direction is defined as a length D1, and a distance between the outer edge portion 22A and the inner edge portion 22B of the second part 22 in the mass-adding film 20 in the Z′ axis direction is defined as a length D2. A distance between the outer edge portion of the first low acoustic velocity region 18A opposite to the second low acoustic velocity region 18B and the outer edge portion of the second low acoustic velocity region 18B opposite to the first low acoustic velocity region 18A in the Z′ axis direction is set as a length E. A distance between the outer edge portion proximal to the first low acoustic velocity region 18A and the outer edge portion proximal to the second low acoustic velocity region 18B in the high acoustic velocity region 17 in the Z′ axis direction is defined as a length E′. In other words, the length E′ is a distance between the inner edge portion of the first low acoustic velocity region 18A proximal to the second low acoustic velocity region 18B and the inner edge portion of the second low acoustic velocity region 18B proximal to the first low acoustic velocity region 18A in the Z′ axis direction. A distance in the Z′ axis direction between the outer edge portion opposite to the second low acoustic velocity region 18B and the outer edge portion proximal to the second low acoustic velocity region 18B in the first low acoustic velocity region 18A is set as a length E1. A distance between the outer edge portion opposite to the first low acoustic velocity region 18A and the outer edge portion proximal to the first low acoustic velocity region 18A in the second low acoustic velocity region 18B in the Z′ axis direction is set as a length E2.

The length A corresponds to a dimension of the mass-adding film 20 in the Z′ axis direction. The length A′ corresponds to a dimension of the high acoustic velocity region 17 in the Z′ axis direction. The length B corresponds to a dimension of the first excitation electrode 14a in the Z′ axis direction and corresponds to the total dimension of the high acoustic velocity region 17, the first low acoustic velocity region 18A, the second low acoustic velocity region 18B, the first outer high acoustic velocity region 19A, and the second outer high acoustic velocity region 19B in the Z′ axis direction. The length B1 corresponds to a dimension of the first outer high acoustic velocity region 19A in the Z′ axis direction, and the length B2 corresponds to a dimension of the second outer high acoustic velocity region 19B in the Z′ axis direction. The length C corresponds to a dimension of the second excitation electrode 14b in the Z′ axis direction. The length C1 corresponds to a dimension of a part in the second excitation electrode 14b extending further than the first excitation electrode 14a to the negative Z′ axis direction side in the Z′ axis direction in plan view. The length C2 corresponds to a dimension of a part in the second excitation electrode 14b extending further than the first excitation electrode 14a to the positive Z′ axis direction side in the Z′ axis direction in plan view. The length D1 corresponds to a dimension of the first part 21 of the mass-adding film 20 in the Z′ axis direction, and the length D2 corresponds to a dimension of the second part 22 of the mass-adding film 20 in the Z′ axis direction. The length E corresponds to the sum of dimensions in the Z′ axis direction of the high acoustic velocity region 17 and the low acoustic velocity region 18. The length E′ corresponds to a dimension of the high acoustic velocity region 17 in the Z′ axis direction. The length E1 corresponds to a dimension of the first low acoustic velocity region 18A in the Z′ axis direction. The length E2 corresponds to a dimension of the second low acoustic velocity region 18B in the Z′ axis direction.

As shown in FIG. 5, in a case where the outer edge portions 21A and 22A of the mass-adding film 20 are parallel to the X axis direction in plan view, the length A is specified by measuring the distance between the outer edge portion 21A and the outer edge portion 22A in the Z′ axis direction. In a case where the inner edge portions 21B and 22B of the mass-adding film 20 are parallel to the X axis direction in plan view, the length A′ is specified by measuring the distance between the inner edge portion 21B and the inner edge portion 22B in the Z′ axis direction.

As shown in FIG. 5, in a case where the outer edge portions 71 and 72 of the first excitation electrode 14a are parallel to the X axis direction in plan view, the length B is specified by measuring the distance between the outer edge portions 71 and 72 in the Z′ axis direction. In a case where the outer edge portions 21A and 22A of the mass-adding film 20 and the outer edge portions 71 and 72 of the first excitation electrode 14a are parallel to the X axis direction in plan view, the length B1 is specified by measuring the distance between the outer edge portion 21A and the outer edge portion 71 in the Z′ axis direction, and the length B2 is specified by measuring the distance between the outer edge portion 22A and the outer edge portion 72 in the Z′ axis direction.

As shown in FIG. 5, in a case where the outer edge portions 81 and 82 of the second excitation electrode 14b are parallel to the X axis direction in plan view, the length C is specified by measuring the distance between the outer edge portion 81 and the outer edge portion 82 in the Z′ axis direction. In a case where the outer edge portions 71 and 72 of the first excitation electrode 14a and the outer edge portions 81 and 82 of the second excitation electrode 14b are parallel to the X axis direction in plan view, the length C1 is specified by measuring the distance between the outer edge portion 71 and the outer edge portion 81 in the Z′ axis direction, and the length C2 is specified by measuring the distance between the outer edge portion 72 and the outer edge portion 82 in the Z′ axis direction.

As shown in FIG. 5, in a case where the outer edge portions 21A and 22A and the inner edge portions 21B and 22B of the mass-adding film 20 are parallel to the X axis direction in plan view, the length D1 is specified by measuring the distance between the outer edge portion 21A and the inner edge portion 21B in the Z′ axis direction, and the length D2 is specified by measuring the distance between the outer edge portion 22A and the inner edge portion 22B in the Z′ axis direction.

As shown in FIG. 5, in a case where the outer edge portions 21A and 22A and the inner edge portions 21B and 22B of the mass-adding film 20 are parallel to the X axis direction in plan view, the length E is specified by measuring the distance between the outer edge portion 21A and the outer edge portion 22A in the Z′ axis direction. In addition, the length E′ is specified by measuring the distance between the inner edge portion 21B and the inner edge portion 22B in the Z′ axis direction, the length E1 is specified by measuring the distance between the outer edge portion 21A and the inner edge portion 21B in the Z′ axis direction, and the length E2 is specified by measuring the distance between the outer edge portion 22A and the inner edge portion 22B in the Z′ axis direction.

However, in a case where the planar shape of the mass-adding film 20 is a polygonal shape, a circular shape, an elliptical shape, or a combination thereof, and the outer edge portions 21A and 22A of the mass-adding film 20 are not parallel in plan view, the length A is specified by another method. For example, the length A may be specified as a maximum value of the distance between the outer edge portion 21A and the outer edge portion 22A. The length A may be specified as an average value or a minimum value of the distance between the outer edge portion 21A and the outer edge portion 22A. In addition, the length A may be specified by dividing the area of the region surrounded by the outer edge portions 21A, 22A, 23A, and 24A of the mass-adding film 20 by the distance between the outer edge portion 23A and the outer edge portion 24A in the X axis direction. In addition, the length A may be specified by measuring the distance between the outer edge portion 21A and the outer edge portion 22A on a tangent line extending in the Z′ axis direction tangent to the inner edge portion 23B or the inner edge portion 24B of the mass-adding film 20 in plan view. The lengths A′, B, B1, B2, C, C1, C2, D1, D2, E, E′, E1, and E2 may be specified in the same manner as the length A.

In the present embodiment, the length E and the length A are substantially equal (E=A), and the length E′ and the length A′ are substantially equal (E′=A′). The length E1 and the length D1 are substantially equal (E1=D1), and the length E2 and the length D2 are substantially equal (E2=D2). The length E1 and the length E2 are substantially equal (E1=E2). Specifically, the relationship of E1=E2=(1±0.04)×(E−E′)/2 is established. The length E1 and the length E2 are greater than the length A′ (A′<E1 and A′<E2). Here, the length E1 and the length E2 may be substantially equal to the length A′ or may be smaller than the length A′.

In the present embodiment, the length A is smaller than the length B, and the length B is smaller than the length C (A<B<C). The length B1 and the length B2 are substantially equal to each other (B1=B2). Specifically, the relationship of B1=B2=(1±0.10)×(B−A)/2 is established. The length C1 and the length C2 are substantially equal (C1=C2). Specifically, the relationship of C1=C2=(1±0.10)×(C−B)/2 is established. As an example, the length C1 is greater than the length B1 (B1<C1), and the length C2 is greater than the length B2 (B2<C2). The length D1 and the length D2 are substantially equal (D1=D2). Specifically, the relationship of D1=D2=(1+0.04)×(A−A′)/2 is established. For example, the length D1 is a length equal to or greater than the length A′ (A′≤D1), and the length D2 is a length equal to or greater than the length A′ (A′≤D2). The ratio A′/B of the length A′ to the length B is, for example, 0.02 or more (0.02≤A′/B). It is desirable that the relationship of 0.05≤A′/B≤0.5 is established. It is still more desirable that the relationship of 0.20≤A′/B≤0.47 is established.

In a case where the relationship of A<B<C is established, the magnitude relationship of the lengths A, A′, B, B1, B2, C, C1, C2, D1, and D2 is not limited to the above. For example, the relationship of B1<B2 or B2<B1 may be established, and the relationship of C1<C2 or C2<C1 may be established. The relationship of C1≤B1 may be established, or the relationship of C2≤B2 may be established. The relationship of D1<D2 or D2<D1 may be established. The relationship of D1<A′ may be established, or the relationship of D2<A′ may be established.

As shown in FIG. 4, the thickness of the quartz crystal element 11 is defined as Tp, the thickness of the first excitation electrode 14a is defined as Te1, the thickness of the second excitation electrode 14b is defined as Te2, and the thickness of the mass-adding film 20 is defined as Tf. In a case where the materials of the first excitation electrode 14a and the mass-adding film 20 are the same and the boundary is unclear, the thickness Tf of the mass-adding film 20 may be specified as a distance in the Y′ axis direction between the surface of the first excitation electrode 14a in the high acoustic velocity region 17 and the surface of the mass-adding film 20 in the low acoustic velocity region 18. In addition, the thickness Tf of the mass-adding film 20 may be specified as the height of the step in the outer edge portions 21A, 22A, 23A, and 24A of the mass-adding film 20 or may be specified as the height of the step in the inner edge portions 21B, 22B, 23B, and 24B of the mass-adding film 20. However, in a case where the height of the step in the outer edge portions 21A, 22A, 23A, and 24A and the height of the step in the inner edge portions 21B, 22B, 23B, and 24B are different from each other, the thickness Tf of the mass-adding film 20 is specified as the height of the step in the inner edge portions 21B, 22B, 23B, and 24B.

The thickness Tp is substantially constant over the high acoustic velocity region 17, the low acoustic velocity region 18, and the outer high acoustic velocity region 19. Similarly, the thicknesses Te1 and Te2 are substantially constant over the high acoustic velocity region 17, the low acoustic velocity region 18, and the outer high acoustic velocity region 19. The thickness Tf is substantially constant over the entire area of the low acoustic velocity region 18. That is, the thicknesses of the first part 21, the second part 22, the third part 23, and the fourth part 24 are substantially equal to each other. The thickness Te1 and the thickness Te2 are substantially equal (Te1=Te2), and the thickness Tf is smaller than the thickness Te1 (Tf<Te1). For example, the thicknesses Te1 and Te2 are approximately 0.05 μm, and the thickness Tf is approximately 0.02 μm.

The magnitude relationship of the thicknesses is not limited to the above. For example, the thickness Tf may be equal to or greater than the thickness Te1 (Te1≤Tf). The thickness Te1 may be smaller than the thickness Te2 (Te1<Te2), and the thickness Te1 may be greater than the thickness Te2 (Te2<Te1).

As shown in FIG. 5, a dimension of the quartz crystal element 11 in the X axis direction is defined as a length Px, and a dimension of the quartz crystal element 11 in the Z′ axis direction is defined as a length Pz. The dimension of the first excitation electrode 14a in the X axis direction is defined as a length Xe1, and the dimension of the first excitation electrode 14a in the Z′ axis direction is defined as a length Ze1. The dimension of the second excitation electrode 14b in the X axis direction is defined as a length Xe2, and the dimension of the second excitation electrode 14b in the Z′ axis direction is defined as a length Ze2. The distance between the outer edge portion 21A of the first part 21 of the mass-adding film 20 and the outer edge portion 71 of the first excitation electrode 14a in the Z′ axis direction is defined as a length Wgz. The distance between the outer edge portion 22A of the second part 22 of the mass-adding film 20 and the outer edge portion 72 of the first excitation electrode 14a in the Z′ axis direction is defined as a length Wgz. The distance between the inner edge portion 21B of the first part 21 of the mass-adding film 20 and the outer edge portion 71 of the first excitation electrode 14a in the Z′ axis direction is defined as a length Wz. A distance between the inner edge portion 22B of the second part 22 of the mass-adding film 20 and the outer edge portion 72 of the first excitation electrode 14a in the Z′ axis direction is defined as a length Wz. The distance between the outer edge portion 23A of the third part 23 of the mass-adding film 20 and the outer edge portion 73 of the first excitation electrode 14a in the X axis direction is defined as a length Wgx. The distance between the outer edge portion 24A of the fourth part 24 of the mass-adding film 20 and the outer edge portion 74 of the first excitation electrode 14a in the X axis direction is defined as a length Wgx. The distance between the inner edge portion 23B of the third part 23 of the mass-adding film 20 and the outer edge portion 73 of the first excitation electrode 14a in the X axis direction is defined as a length Wx. The distance between the inner edge portion 24B of the fourth part 24 of the mass-adding film 20 and the outer edge portion 74 of the first excitation electrode 14a in the X axis direction is defined as a length Wx. The distance between the first part 21 and the second part 22 of the mass-adding film 20 in the Z′ axis direction is defined as a length Zf, and a distance between the third part 23 and the fourth part 24 of the mass-adding film 20 in the X axis direction is defined as a length Xf.

The length Ze2 corresponds to the length C (Ze2=C). The length Ze1 corresponds to the length B (Ze1=B). The length Wgz corresponds to the lengths B1 and B2 (Wgz=B1=B2). The length Wz corresponds to the sum of the length B1 and the length D1 and the sum of the length B2 and the length D2 (Wz=B1+D1=B2+D2). The length Zf corresponds to the length A′ (Zf=A′). The dimension of the mass-adding film 20 in the Z′ axis direction can be represented by 2×Wz+Zf−2×Wgz, and is a size equal to or smaller than the dimension Ze2 in the Z′ axis direction of the second excitation electrode 14b (2×Wz+Zf−2×Wgz≤Ze2). In addition, the dimension of the mass-adding film 20 in the X axis direction can be represented by 2×Wx+Xf−2×Wgx, and is a size equal to or smaller than the dimension Xe2 of the second excitation electrode 14b in the X axis direction (2×Wx+Xf−2×Wgx≤Xe2). The length Wgz is, for example, a size substantially equal to the length Wgx (Wgz=Wgx). Here, the length Wgz may be smaller than the length Wgx (Wgz<Wgx), and the length Wgz may be greater than the length Wgx (Wgx<Wgz).

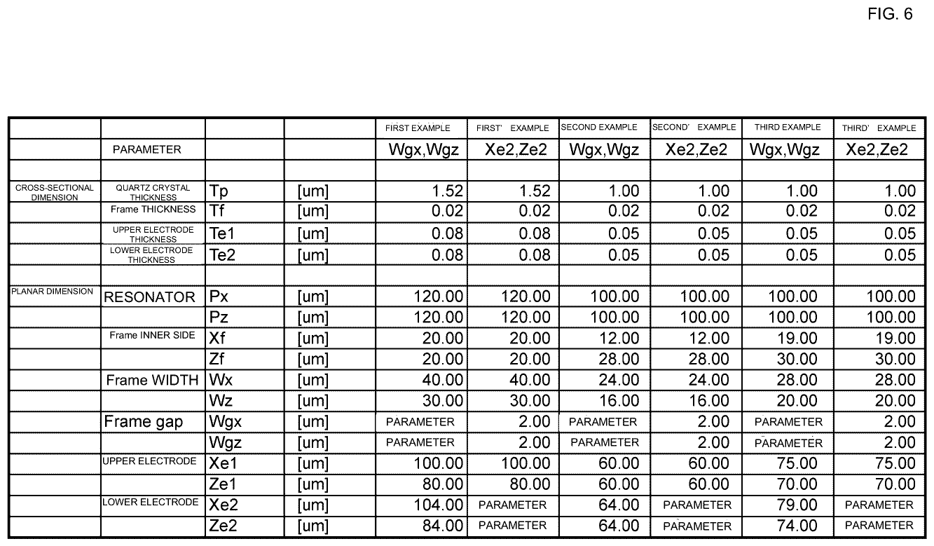

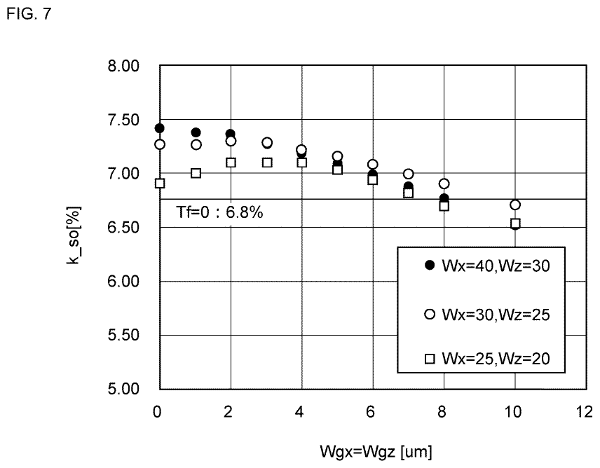

Next, simulation results of Examples based on the first embodiment will be described with reference to FIGS. 6 to 16. FIG. 6 is a table showing simulation conditions based on the first embodiment. FIGS. 7 to 16 are graphs showing simulation results based on the first embodiment.

### First Example

Tp=1.52 μm
Tf=0.02 μm
Te1=Te2=0.08 μm
Px=Pz=120 μm
Xf=Zf=20 μm
Wx=40 μm
Wz=30 μm
Wgx: variable
Wgz: variable
Xe1=100 μm
Ze1=80 μm
Xe2=104 μm
Ze2=84 μm

### First′ Example

Wgx=Wgz=2 μm
Xe2: variable
Ze2: variable

Other than the above, First′ Example is the same as First Example.

### Second Example

Tp=1.00 μm
Tf=0.02 μm
Te1=Te2=0.05 μm
Px=Pz=100 μm
Xf=12 μm
Zf=28 μm
Wx=24 μm
Wz=16 μm
Wgx: variable
Wgz: variable
Xe1=Ze1=60 μm
Xe2=Ze2=64 μm

### Second′ Example

Wgx=Wgz=2 μm
Xe2: variable
Ze2: variable

Other than the above, Second′ Example is the same as Second Example.

### Third Example

Tp=1.00 μm
Tf=0.02 μm
Te1=Te2=0.05 μm
Px=Pz=100 μm
Xf=19 μm
Zf=30 μm
Wx=28 μm
Wz=20 μm
Wgx: variable
Wgz: variable
Xe1=75 μm
Ze1=70 μm
Xe2=79 μm
Ze2=74 μm

### Third′ Example

Wgx=Wgz=2 μm
Xe2: variable
Ze2: variable

Other than the above, Third′ Example is the same as Third Example.

FIG. 7 shows the simulation results based on First Example. The vertical axis indicates the electromechanical coupling coefficient k of the S0 mode, which is the main mode (hereinafter also referred to as “k_S0”), and the horizontal axis indicates Wgx=Wgz. In the graph, the simulation result of k_S0 in First Example (Wx=40 μm, Wz=30 μm), the simulation result of k_S0 in the configuration in which Wx was changed to 30 μm and Wz was changed to 25 μm based on First Example, and the simulation result of k_S0 in the configuration in which Wx was changed to 25 μm and Wz was changed to 20 μm based on First Example are plotted. In a case where Tf=0, that is, in a case of a configuration in which the mass-adding film 20 is not provided, k_S0 is about 6.8%. Xf and Zf are determined by the following expressions Xf=Xe1−Wx×2 and Zf=Ze1−Wz×2, and thus Xf and Zf are changed in conjunction with Wx and Wz.

In First Example, when B′=Wgx=Wgz≤8 μm, k_S0 is improved over 6.8% when Tf=0. From the configuration of First Example, the same tendency can be obtained even when Wx and Wz are changed. In a case where the ratio of Wx to Xe1 is 25% to 40%, and the ratio of Wz to Ze1 is 25% to 37.5%, at least, 6.8%<k_S0 is satisfied in a case where B′=Wgx=Wgz<8 μm, and 6.8%<k_S0 is satisfied in a case where B′=Wgx=Wgz≤7 μm, regardless of the magnitudes of Wx and Wz.

In a case where the planar shape of the mass-adding film is a rectangular frame shape continuous in the peripheral direction, the condition, under which 6.8%<k_S0 is satisfied in a case where B′=Wgx=Wgz<8 μm regardless of the magnitudes of Wx and Wz, is that, when expressed as an area ratio of the mass-adding film to the area of the first excitation electrode, the area ratio is 75% to 95%. In addition, in a case where the planar shape of the mass-adding film is two strip shapes parallel to the X axis direction, the condition, under which 6.8%<k_S0 is satisfied in a case where B′=Wgz<8 μm regardless of the magnitude of Wz, is that the area ratio is 50% to 80%. Similarly, in a case where the planar shape of the mass-adding film is two strip shapes parallel to the Z′ axis direction, the condition, under which 6.8%<k_S0 is satisfied in a case where B′=Wgx<8 μm regardless of the magnitude of Wx, is that the area ratio is 50% to 80%.

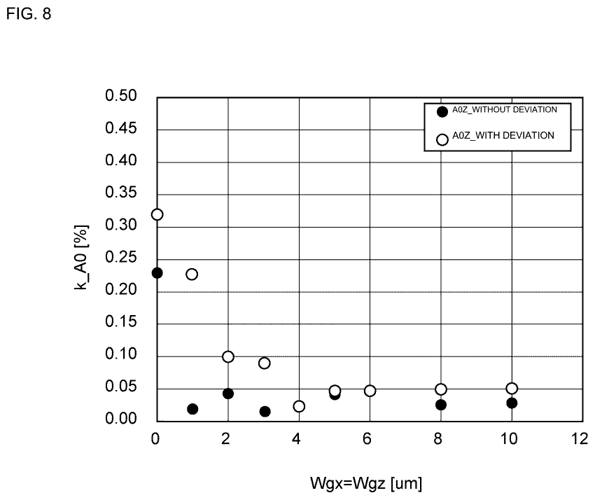

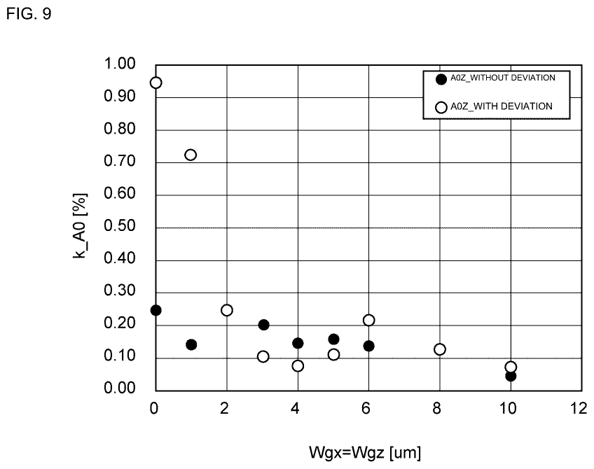

FIG. 8 shows simulation results based on First Example. FIG. 9 shows simulation results based on the Second Example. In FIGS. 8 and 9, the vertical axis indicates the electromechanical coupling coefficient k (hereinafter also referred to as “k_A0”) in the A0 mode which is the spurious mode, and the horizontal axis indicates Wgx=Wgz. In the graphs of FIG. 8 and FIG. 9, the simulation results of k_A0Z in the configuration in which the positional deviation between the mass-adding film 20 and the second excitation electrode 14b does not occur and the simulation results of k_A0Z in the configuration in which the positional deviation occurs are plotted. The simulation result of k_A0Z in the configuration in which the positional deviation occurs is obtained by performing the simulation on the assumption that the mass-adding film 20 deviates in position by 0.5 μm in the positive X axis direction and the positive Z′ axis direction, and the second excitation electrode 14b deviates in position by 0.5 μm in the negative X axis direction and the negative Z′ axis direction.

In both FIGS. 8 and 9, k_A0Z in the configuration with positional deviation is substantially equal to k_A0Z in the configuration without positional deviation in a range of 2 μm≤B′=Wgx=Wgz≤10 μm. That is, in a case where 2 μm≤B′=Wgx=Wgz≤10 μm, the increase in k_A0Z is suppressed regardless of the dimensions and the positional deviation of the first excitation electrode 14a, the second excitation electrode 14b, and the mass-adding film 20.

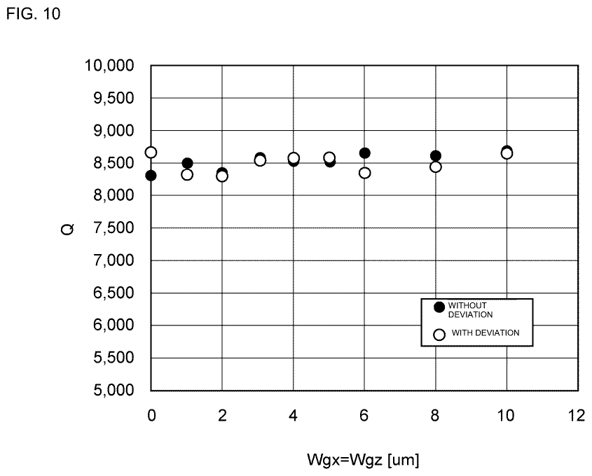

FIG. 10 shows the simulation results based on First Example. The vertical axis indicates the Q factor, and the horizontal axis indicates Wgx=Wgz. In the graph, the simulation results of the Q factor in the configuration without positional deviation of the mass-adding film 20 and the second excitation electrode 14b and the simulation results of the Q factor in the configuration with positional deviation are plotted. The direction and amount of positional deviation in the configuration with positional deviation in FIG. 10 are the same as the direction and amount of positional deviation in the configuration with positional deviation in FIGS. 8 and 9.

In the configuration without positional deviation, the Q factor is substantially unchangeable in a range of 0<B′=Wgx=Wgz≤10 μm. In addition, the Q factor in the configuration with positional deviation is substantially equal to the Q factor in the configuration without positional deviation. That is, the Q factor is substantially constant regardless of the magnitude of B′=Wgx=Wgz and whether or not positional deviation occurs.

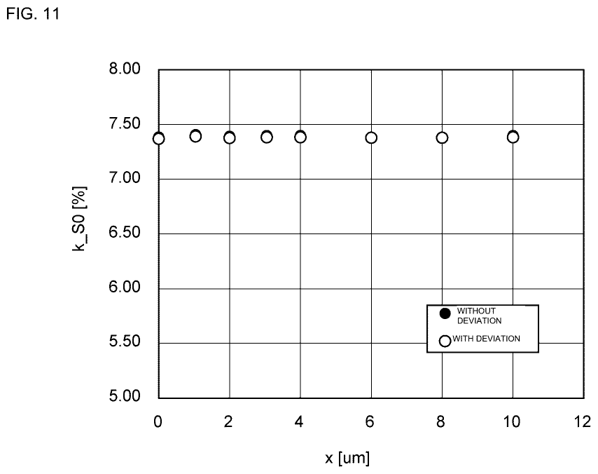

FIG. 11 shows the simulation results based on First′ Example. The vertical axis indicates k_S0, and the horizontal axis indicates x=C−B=Ze2−Ze1. In the graph, the simulation result of k_S0 in the configuration in which positional deviation of the mass-adding film 20 and the second excitation electrode 14b does not occur and the simulation result of k_S0 in the configuration in which the positional deviation occurs are plotted. The direction and amount of positional deviation in the configuration with positional deviation in FIG. 11 are the same as the direction and amount of positional deviation in the configuration with positional deviation in FIGS. 8 and 9.

In the configuration without positional deviation, k_S0 does not substantially change in the range of 0<x≤10 μm. In addition, in a range of 0<x≤10 μm, k_S0 in the configuration with positional deviation is substantially equal to k_S0 in the configuration without positional deviation. That is, k_S0 is substantially constant regardless of the magnitude of x and whether or not positional deviation occurs.

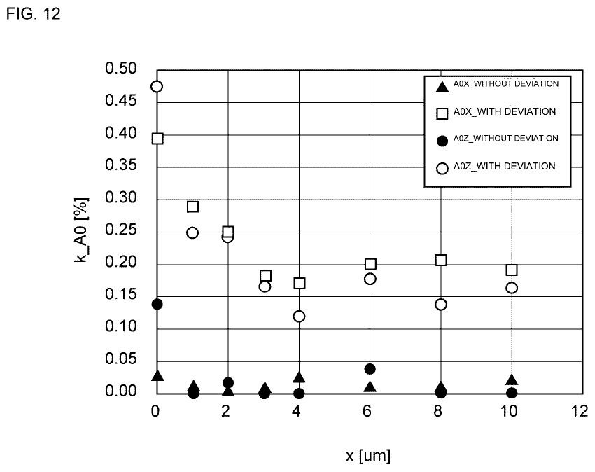

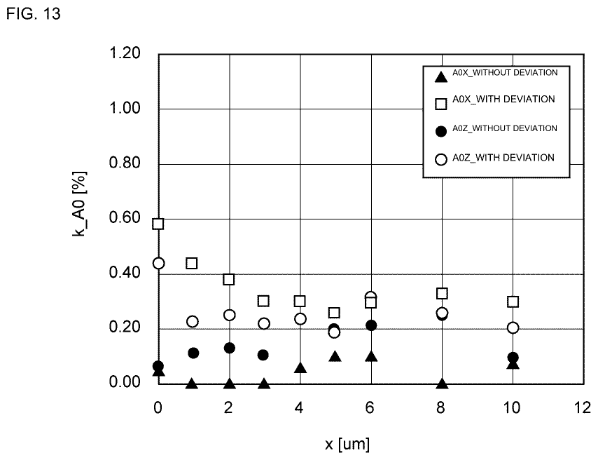

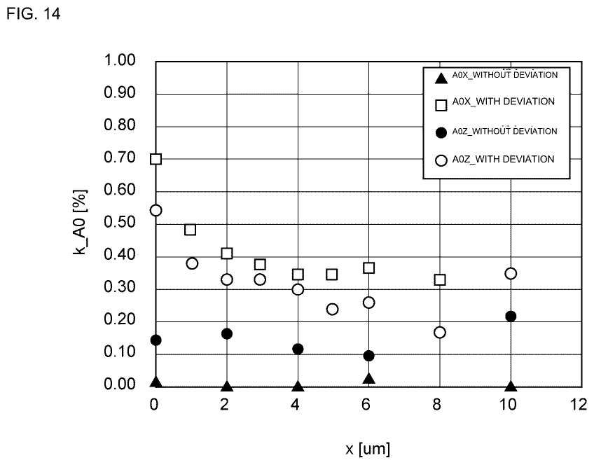

FIG. 12 shows simulation results based on First′ Example, FIG. 13 shows simulation results based on Second′ Example, and FIG. 14 shows simulation results based on Third′ Example. In FIGS. 12 to 14, the vertical axis indicates k_A0, and the horizontal axis indicates x=C−B=Ze2−Ze1. In the graphs of FIGS. 12 to 14, the simulation results of k_A0X and k_A0Z in the configuration in which the positional deviation between the mass-adding film 20 and the second excitation electrode 14b does not occur and the simulation results of k_A0X and k_A0Z in the configuration in which the positional deviation occurs are plotted. The direction and amount of positional deviation in the configuration with positional deviation in FIGS. 12 to 14 are the same as the direction and amount of positional deviation in the configuration with positional deviation in FIGS. 8 and 9.

In FIG. 12, both k_A0X and k_A0Z are sufficiently reduced and substantially constant in the range of 3 μm≤x≤10 μm. That is, in a range of 3 μm≤x≤10 μm, the effect of suppressing excitation in the A0 mode is stable. In addition, in the range of 3 μm≤x≤10 μm, k_A0X and k_A0Z in the configuration with positional deviation are substantially equal to k_A0X and k_A0Z in the configuration without positional deviation. That is, in the range of 3 μm≤x≤10 μm, k_A0X and k_A0Z are substantially constant regardless of the magnitude of x and whether or not positional deviation occurs. Also in FIGS. 13 and 14, k_A0X and k_A0Z show the same tendency. That is, the increase in k_A0 is suppressed regardless of the dimensions and the positional deviation of the first excitation electrode 14a, the second excitation electrode 14b, and the mass-adding film 20.

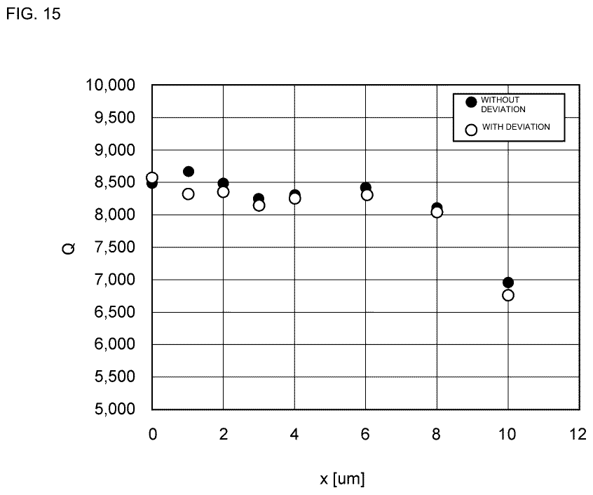

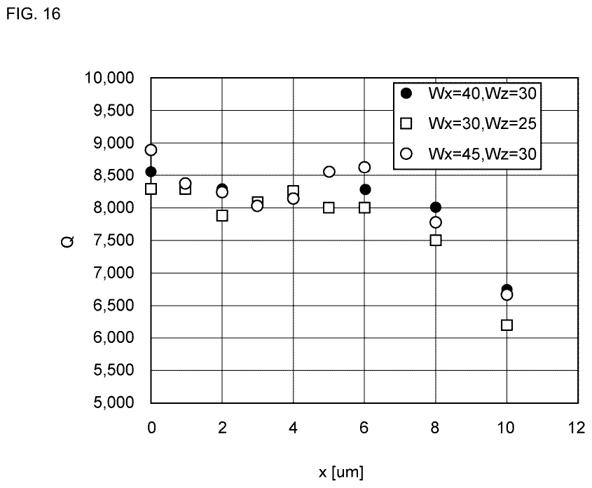

FIGS. 15 and 16 show simulation results based on First′ Example. In FIGS. 15 and 16, the vertical axis indicates the Q factor, and the horizontal axis indicates x=C−B=Ze2−Ze1. In the graph of FIG. 15, the simulation results of the Q factor in the configuration without positional deviation of the mass-adding film 20 and the second excitation electrode 14b and the simulation results of the Q factor in the configuration with positional deviation are plotted. The direction and amount of positional deviation in the configuration with positional deviation in FIG. 15 are the same as the direction and amount of positional deviation in the configuration with positional deviation in FIGS. 8 and 9. In the graph of FIG. 16, the simulation result of the Q factor in First Example (Wx=40 μm, Wz=30 μm), the simulation result of the Q factor in the configuration in which Wx was changed to 30 μm and Wz was changed to 25 μm based on First Example, and the simulation result of the Q factor in the configuration in which Wx was changed to 45 μm and Wz was changed to 30 μm based on First Example are plotted.

As shown in FIG. 15, the Q factor in the configuration without positional deviation is a magnitude of 80% or more of the Q factor in a case where x=0 μm in a range of 0<x≤8 μm. The Q factor in the configuration with the positional deviation shows the same tendency as the Q factor in the configuration without positional deviation and is substantially equal to the Q factor in the configuration without positional deviation. That is, in a range of 0<x≤8 μm, a decrease in Q factor is suppressed regardless of whether or not positional deviation occurs.

As shown in FIG. 16, even in a case where Wx and Wz are changed based on First Example, the Q factor shows the same tendency. That is, in the range of 0<x≤8 μm, the decrease in Q factor is suppressed regardless of the dimensions of the first excitation electrode 14a, the second excitation electrode 14b, and the mass-adding film 20.

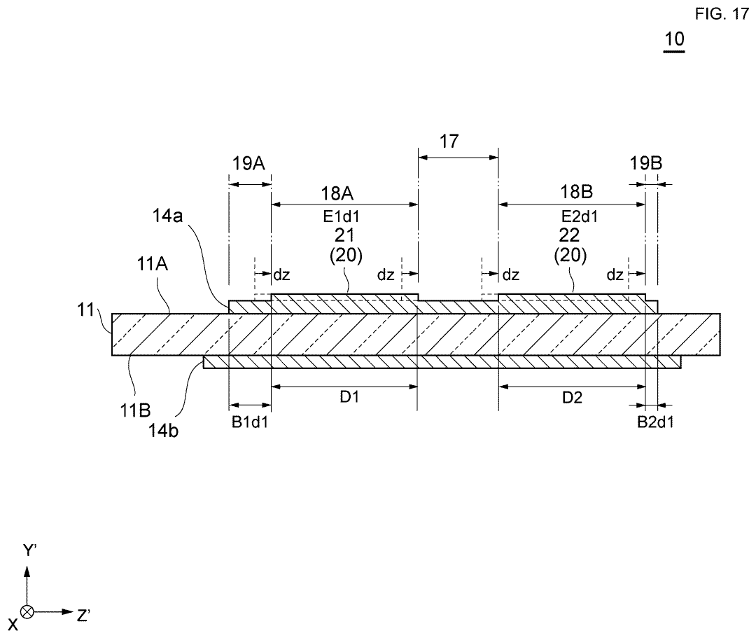

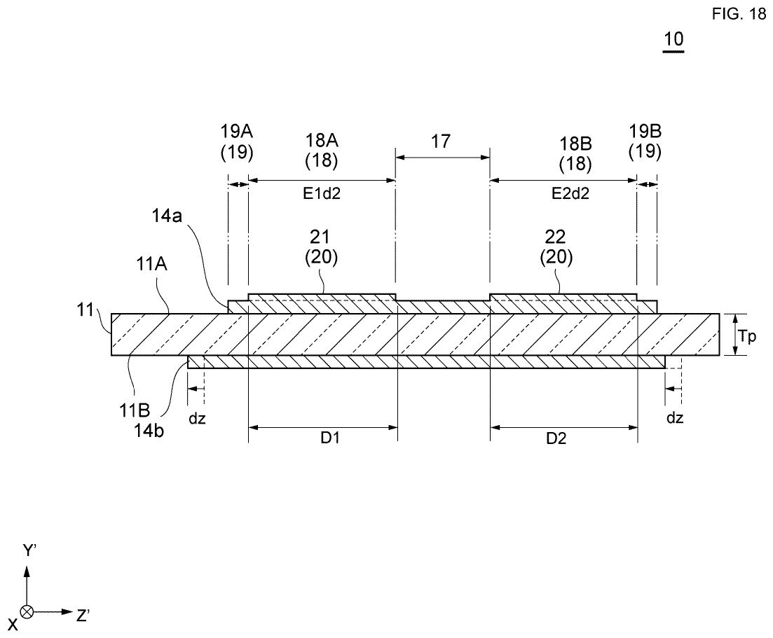

Next, the influence of positional deviation will be described with reference to FIGS. 17 and 18. FIG. 17 is a view for describing the influence of positional deviation in the first embodiment. FIG. 18 is a view for describing the influence of positional deviation in the first embodiment. FIG. 17 is a cross-sectional view of the quartz crystal resonator 10 in a case where the mass-adding film 20 deviates by dz in the positive Z′ axis direction. FIG. 18 is a cross-sectional view of the quartz crystal resonator 10 in a case where the second excitation electrode 14b deviates by dz in the negative Z′ axis direction.

As shown in FIG. 17, in a case where the mass-adding film 20 deviates by dz in the positive Z′ axis direction, when a length of the first outer high acoustic velocity region 19A in the Z′ axis direction is defined as B1d1, the length B1d1 is greater than the length B1 by the amount of deviation dz. That is, B1d1=B1+dz is established. In a case where the mass-adding film 20 deviates by dz in the positive Z′ axis direction, when a length of the second outer high acoustic velocity region 19B in the Z′ axis direction is defined as B2d1, the length B2d1 is smaller than the length B2 by the amount of deviation dz. That is, B2d1=B2−dz is established.

As shown in FIG. 17, in a case where the mass-adding film 20 deviates by dz in the positive Z′ axis direction, when a length of the first low acoustic velocity region 18A in the Z′ axis direction is defined as E1d1, the length E1d1 does not change from the length E1. That is, E1d1=E1=D1 is established. In a case where the mass-adding film 20 deviates by dz in the positive Z′ axis direction, when a length of the second low acoustic velocity region 18B in the Z′ axis direction is defined as E2d1, the length E2d1 does not change from the length E2. That is, E2d1=E2=D2 is established. Therefore, in the present embodiment, even in a case where the mass-adding film 20 deviates by dz in the positive Z′ axis direction, the balance of the lengths of the first low acoustic velocity region 18A and the second low acoustic velocity region 18B in the Z′ axis direction does not change, and the relationship of E1d1=E2d1 is established. Therefore, even when the mass-adding film 20 deviates by dz in the positive Z′ axis direction, the increase in k_A0 is suppressed, and the decrease in k_S0 is suppressed.

In a case where B2<dz, the second part 22 of the mass-adding film 20 extends from the first excitation electrode 14a to the positive Z′ axis direction side in plan view. Therefore, a part of the second part 22 of the mass-adding film 20 that does not overlap with the first excitation electrode 14a comes out, and the balance of the lengths of the first low acoustic velocity region 18A and the second low acoustic velocity region 18B in the Z′ axis direction changes. In order to maintain the balance of the lengths of the first low acoustic velocity region 18A and the second low acoustic velocity region 18B in the Z′ axis direction, it is desirable to satisfy the relationship of dz≤B′=B1=B2. The positional deviation on the same surface is, for example, a maximum of about 0.3 μm, and thus it is desirable that 0.5 μm≤B′, more desirable that 1 μm≤B′, and still more desirable that 2 μm≤B′.

As shown in FIG. 18, in a case where the second excitation electrode 14b deviates by dz in the negative Z′ axis direction, when a length of the first low acoustic velocity region 18A in the Z′ axis direction is defined as E1d2, the length E1d2 does not change from the length E1. That is, E1d2=E1=D1 is established. In a case where the second excitation electrode 14b deviates by dz in the negative Z′ axis direction, when a length of the second low acoustic velocity region 18B in the Z′ axis direction is defined as E2d2, the length E2d2 does not change from the length E2. That is, E2d2=E2=D2 is established. Therefore, in the present embodiment, even in a case where the second excitation electrode 14b deviates by dz in the negative Z′ axis direction, the balance of the lengths of the first low acoustic velocity region 18A and the second low acoustic velocity region 18B in the Z′ axis direction does not change, and the relationship of E1d2=E2d2 is established. Therefore, even when the second excitation electrode 14b deviates by dz in the negative Z′ axis direction, the increase in k_A0 is suppressed, and the decrease in k_S0 is suppressed.

In a case where C2<dz, the second excitation electrode 14b extends from the first excitation electrode 14a to the positive Z′ axis direction side in plan view. Therefore, a part of the first excitation electrode 14a that does not overlap with the second excitation electrode 14b comes out, and the balance of the lengths of the first outer high acoustic velocity region 19A and the second outer high acoustic velocity region 19B in the Z′ axis direction changes. In order to maintain the balance of the lengths of the first outer high acoustic velocity region 19A and the second outer high acoustic velocity region 19B in the Z′ axis direction, it is desirable to satisfy the relationship of dz≤C′=C1=C2. The positional deviation between different surfaces is, for example, a maximum of about 0.7 μm, and thus it is desirable that 1 μm≤C′, more desirable that 2 μm≤C′, and still more desirable that 4 μm≤C′.

As described above, according to the present embodiment, the mass-adding film 20 is provided on the first excitation electrode 14a. The mass-adding film 20 is provided along the outer edge portion of the first excitation electrode 14a, and when a dimension of the mass-adding film 20 in the Z′ axis direction is defined as A and a dimension of the second excitation electrode 14b in the Z′ axis direction is defined as C, the relationship of A≤C is established. In addition, the outer edge portion 21A of the first part 21 and the outer edge portion 22A of the second part 22 of the mass-adding film 20 overlap with the second excitation electrode 14b.

Accordingly, even in a case where the positions of the mass-adding film 20 and the second excitation electrode 14b deviate from each other, it is possible to suppress the deterioration of the balance of the dimensions of the first low acoustic velocity region 18A and the second low acoustic velocity region 18B. Therefore, it is possible to suppress an increase in the electromechanical coupling coefficient k_A0 of the spurious mode and a decrease in the electromechanical coupling coefficient k_S0 of the main mode.

In addition, in the present embodiment, when a dimension of the first part 21 of the mass-adding film 20 in the Z′ axis direction is defined as D1, a dimension of the second part 22 of the mass-adding film 20 in the Z′ axis direction is defined as D2, and a distance between the first part 21 and the second part 22 of the mass-adding film 20 in the Z′ axis direction is defined as A, D1 and D2 are substantially equal to each other, and for example, D1=(1±0.04)×(A−A′)/2 μm and D2=(1+0.04)×(A−A′)/2 μm.

Accordingly, it is possible to suppress the spurious vibration in the A0 mode.

In addition, in the present embodiment, when a distance between the first part 21 and the second part 22 of the mass-adding film 20 in the Z′ axis direction is defined as A′ and a dimension of the first excitation electrode 14a in the Z′ axis direction is defined as B, the relationship of A′/B≤0.5 is established.

Accordingly, the area of the first part 21 or the second part 22 of the mass-adding film 20 is excessively large, and thus it is possible to suppress a decrease in the effect of reducing the spurious vibration caused by the mass-adding film 20.

In addition, in the present embodiment, the relationship of 0.05≤A′/B is established.

Accordingly, in a case where positional deviation of the mass-adding film 20 occurs with respect to the first excitation electrode 14a, the extension of the majority of the first part 21 or the second part 22 of the mass-adding film 20 to the outer side portion of the first excitation electrode 14a in plan view is suppressed. That is, it is possible to suppress the deterioration of the balance of the dimensions of the first low acoustic velocity region 18A and the second low acoustic velocity region 18B. Therefore, it is possible to sufficiently suppress the increase in k_A0 and the decrease in k_S0.

In addition, in the present embodiment, when a distance between the outer edge portion 21A of the first part 21 of the mass-adding film 20 and the outer edge portion 71 of the first excitation electrode 14a in the Z′ axis direction, and a distance between the outer edge portion 22A of the second part 22 of the mass-adding film 20 and the outer edge portion 72 of the first excitation electrode 14a in the Z′ axis direction are defined as B′, the relationship of 2 μm≤B′ is established.

Accordingly, an increase in k_A0 can be suppressed.

In addition, in the present embodiment, the relationship of B′≤8 μm is established.

Accordingly, a decrease in k_S0 can be suppressed.

In addition, in the present embodiment, when the dimension of the second excitation electrode 14b in the Z′ axis direction is defined as C, the relationship of 3 μm≤C−B is established.

Accordingly, an increase in k_A0 can be suppressed.

In addition, in the present embodiment, the relationship of C−B≤10 μm is established.

As a result, a decrease in Q factor can be suppressed.

Hereinafter, other embodiments will be described. The same or similar configurations as the configurations described in the first embodiment are defined as the same or similar reference numerals, and descriptions thereof are appropriately omitted. In addition, the same operational effects according to the same configuration will not be sequentially described.

### Second Embodiment

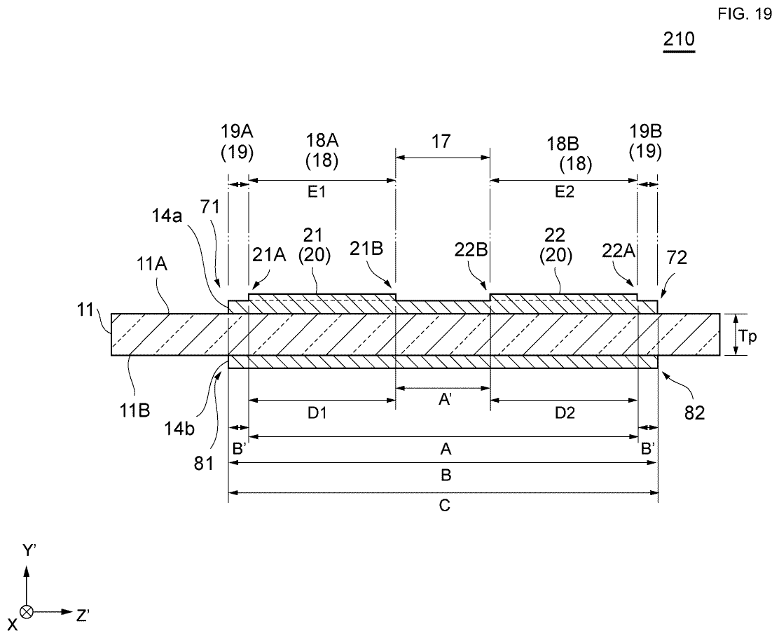

Next, a configuration of a quartz crystal resonator 210 according to a second embodiment will be described with reference to FIG. 19. FIG. 19 is a cross-sectional view of the quartz crystal resonator according to the second embodiment.

In plan view, the outer edge portion 71 of the first excitation electrode 14a overlaps with the outer edge portion 81 of the second excitation electrode 14b, and the outer edge portion 72 of the first excitation electrode 14a overlaps with the outer edge portion 82 of the second excitation electrode 14b. The outer edge portion 21A of the first part 21 and the outer edge portion 22A of the second part 22 of the mass-adding film 20 are positioned between the outer edge portion 71 and the outer edge portion 72 of the first excitation electrode 14a. The length B is substantially equal to the length C and is greater than the length A (A<B=C). The length E1 is substantially equal to the length D1 (E1=D1), the length E1 is substantially equal to the length D1 (E2=D2), and the length E1 is substantially equal to the length E2 (E1=E2).

In plan view, both the outer edge portion 71 of the first excitation electrode 14a and the outer edge portion 81 of the second excitation electrode 14b are farther from the central portion of the first excitation electrode 14a than the outer edge portion of the first low acoustic velocity region 18A. The outer edge portion 71 and the outer edge portion 81 are farther from the central portion of the first excitation electrode 14a by approximately the same distance. Both the outer edge portion 71 of the first excitation electrode 14a and the outer edge portion 81 of the second excitation electrode 14b are farther from the central portion of the first excitation electrode 14a than the outer edge portion of the second low acoustic velocity region 18B. The outer edge portion 72 and the outer edge portion 82 are farther from the central portion of the first excitation electrode 14a by approximately the same distance.

### Third Embodiment

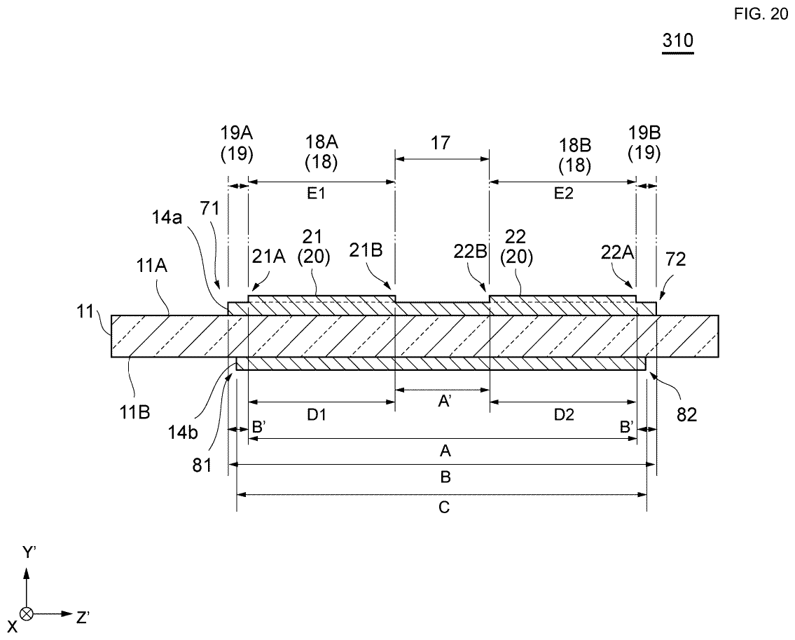

Next, a configuration of a quartz crystal resonator 310 according to a third embodiment will be described with reference to FIG. 20. FIG. 20 is a cross-sectional view of the quartz crystal resonator according to the third embodiment.

In plan view, the outer edge portion 81 of the second excitation electrode 14b is positioned between the outer edge portion 71 of the first excitation electrode 14a and the outer edge portion 21A of the first part 21 of the mass-adding film 20. The outer edge portion 82 of the second excitation electrode 14b is positioned between the outer edge portion 72 of the first excitation electrode 14a and the outer edge portion 22A of the second part 22 of the mass-adding film 20. The outer edge portion 21A of the first part 21 and the outer edge portion 22A of the second part 22 of the mass-adding film 20 are positioned between the outer edge portion 81 and the outer edge portion 82 of the second excitation electrode 14b. The outer edge portion 81 and the outer edge portion 82 of the second excitation electrode 14b are positioned between the outer edge portion 71 and the outer edge portion 72 of the first excitation electrode 14a. The length B is greater than the length C, and the length Cis greater than the length A (A<C<B). The length E1 is substantially equal to the length D1 (E1=D1), the length E1 is substantially equal to the length D1 (E2=D2), and the length E1 is substantially equal to the length E2 (E1=E2).

In plan view, both the outer edge portion 71 of the first excitation electrode 14a and the outer edge portion 81 of the second excitation electrode 14b are farther from the central portion of the first excitation electrode 14a than the outer edge portion of the first low acoustic velocity region 18A. The outer edge portion 71 is farther from the central portion of the first excitation electrode 14a than the outer edge portion 81. Both the outer edge portion 71 of the first excitation electrode 14a and the outer edge portion 81 of the second excitation electrode 14b are farther from the central portion of the first excitation electrode 14a than the outer edge portion of the second low acoustic velocity region 18B. The outer edge portion 72 is farther from the central portion of the first excitation electrode 14a than the outer edge portion 82.

### Fourth Embodiment

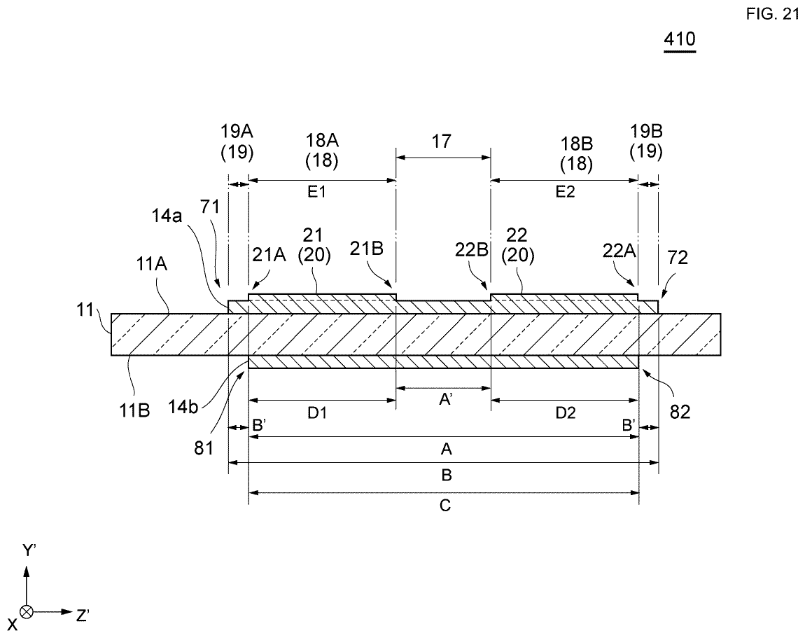

Next, a configuration of a quartz crystal resonator 410 according to a fourth embodiment will be described with reference to FIG. 21. FIG. 21 is a cross-sectional view of the quartz crystal resonator according to the fourth embodiment.

In plan view, the outer edge portion 21A of the first part 21 and the outer edge portion 22A of the second part 22 of the mass-adding film 20 overlap with the outer edge portion 81 of the second excitation electrode 14b. The outer edge portion 21A of the first part 21 and the outer edge portion 22A of the second part 22 of the mass-adding film 20 are positioned between the outer edge portion 71 and the outer edge portion 72 of the first excitation electrode 14a. The length A is substantially equal to the length C and is smaller than the length B (A=C<B). The length E1 is substantially equal to the length D1 (E1=D1), the length E1 is substantially equal to the length D1 (E2=D2), and the length E1 is substantially equal to the length E2 (E1=E2).

In plan view, the outer edge portion of the first low acoustic velocity region 18A overlaps not only with the outer edge portion 21A of the first part 21 of the mass-adding film 20 but also with the outer edge portion 81 of the second excitation electrode 14b. The outer edge portion of the second low acoustic velocity region 18B overlaps not only with the outer edge portion 22A of the second part 22 of the mass-adding film 20 but also with the outer edge portion 82 of the second excitation electrode 14b.

In plan view, one of the outer edge portion 71 of the first excitation electrode 14a and the outer edge portion 81 of the second excitation electrode 14b, that is, the outer edge portion 71 is farther from the central portion of the first excitation electrode 14a than the outer edge portion of the first low acoustic velocity region 18A. One of the outer edge portion 72 of the first excitation electrode 14a and the outer edge portion 82 of the second excitation electrode 14b, that is, the outer edge portion 72 is farther from the central portion of the first excitation electrode 14a than the outer edge portion of the second low acoustic velocity region 18B.

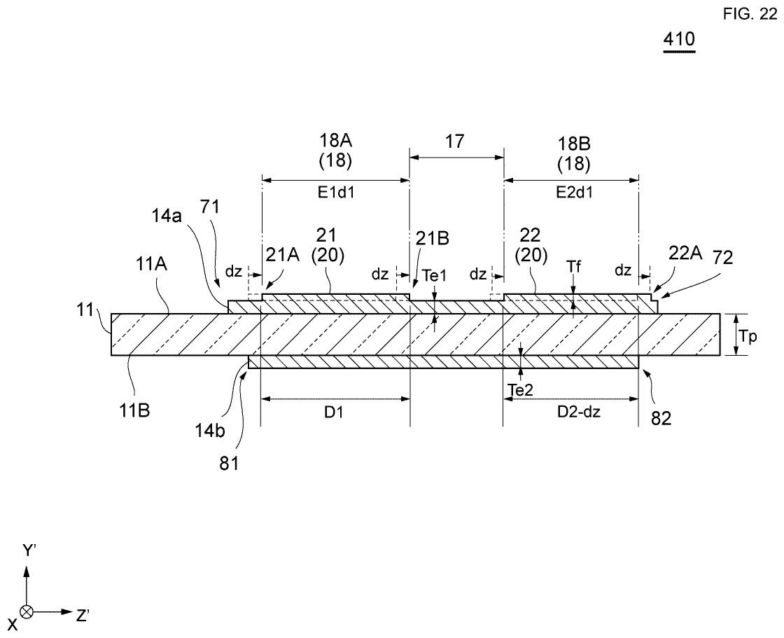

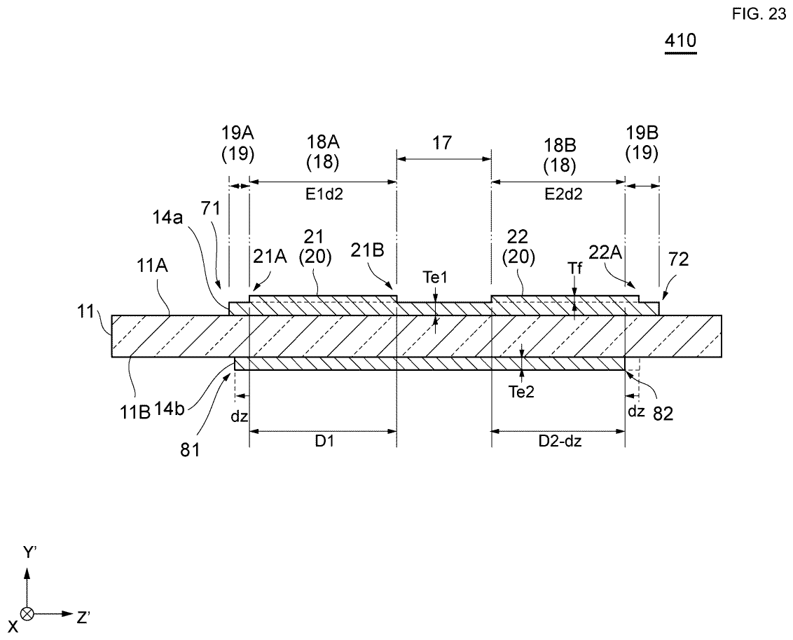

Next, the influence of positional deviation in the fourth embodiment will be described with reference to FIGS. 22 and 23. FIGS. 22 and 23 are views for describing the influence of positional deviation in the fourth embodiment. FIG. 22 is a cross-sectional view of the quartz crystal resonator 410 in a case where the mass-adding film 20 deviates by dz in the positive Z′ axis direction. FIG. 23 is a cross-sectional view of the quartz crystal resonator 410 in a case where the second excitation electrode 14b deviates by dz in the negative Z′ axis direction.

In either case where the mass-adding film 20 deviates by dz in the positive Z′ axis direction as shown in FIG. 22, or where the second excitation electrode 14b deviates by dz in the negative Z′ axis direction as shown in FIG. 23, in plan view, the second part 22 of the mass-adding film 20 extends from the second excitation electrode 14b to the positive Z′ axis direction side by the amount of deviation dz. Therefore, the region where the first excitation electrode 14a, the second excitation electrode 14b, and the second part 22 of the mass-adding film 20 overlap with each other is reduced by the amount of deviation dz. That is, the length E2d1 and the length E2d2 are represented by E2d1=E2d2=E2−dz=D2−dz. The length E1d1 and the length E2d2 do not change from the length E1. That is, the length E1d1 and the length E2d2 are represented by E1d1=E1d2=E1=D1. Therefore, in the present embodiment, in a case where the mass-adding film 20 deviates by dz in the positive Z′ axis direction, the balance of the lengths of the first low acoustic velocity region 18A and the second low acoustic velocity region 18B in the Z′ axis direction changes, and the relationship of E2d1<E1d1 is established. In addition, even in a case where the second excitation electrode 14b deviates by dz in the positive Z′ axis direction, the balance of the lengths of the first low acoustic velocity region 18A and the second low acoustic velocity region 18B in the Z′ axis direction changes, and the relationship of E2d2<E1d2 is established. However, the outer edge portion 22A of the second part 22 of the mass-adding film 20 is positioned on the positive Z′ direction side of the second low acoustic velocity region 18B, and the outer edge portion 72 of the first excitation electrode 14a is positioned further on the positive Z′ direction side. In other words, as one moves to the positive Z′ direction side starting from the second low acoustic velocity region 18B, the total thickness of the quartz crystal resonator 410 changes from Tp+Te1+Te2+Tf to Tp+Te1+Tf, then to Tp+Te1, and finally to Tp. On the positive Z′ direction side of the second low acoustic velocity region 18B, the total thickness of the quartz crystal resonator 410 gradually decreases, and thus the phase change is accelerated. As a result, the problem caused by the change in the balance of the lengths of the first low acoustic velocity region 18A and the second low acoustic velocity region 18B in the Z′ axis direction is relieved.

### Fifth Embodiment

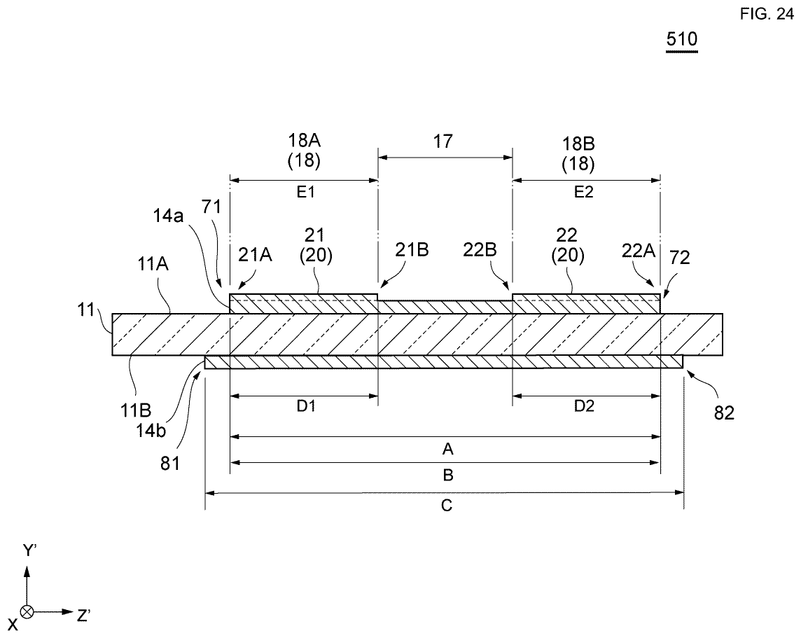

Next, a configuration of a quartz crystal resonator 510 according to a fifth embodiment will be described with reference to FIG. 24. FIG. 24 is a cross-sectional view of the quartz crystal resonator according to the fifth embodiment.

In plan view, the outer edge portion 21A of the first part 21 of the mass-adding film 20 overlaps with the outer edge portion 71 of the first excitation electrode 14a, and the outer edge portion 22A of the second part 22 of the mass-adding film 20 overlaps with the outer edge portion 72 of the first excitation electrode 14a. The outer edge portion 21A of the first part 21 and the outer edge portion 22A of the second part 22 of the mass-adding film 20 are positioned between the outer edge portion 81 and the outer edge portion 82 of the second excitation electrode 14b. The length A is substantially equal to the length B and is smaller than the length C (A=B<C). The length E1 is substantially equal to the length D1 (E1=D1), the length E1 is substantially equal to the length D1 (E2=D2), and the length E1 is substantially equal to the length E2 (E1=E2).

In plan view, the outer edge portion of the first low acoustic velocity region 18A overlaps not only with the outer edge portion 21A of the first part 21 of the mass-adding film 20 but also with the outer edge portion 71 of the first excitation electrode 14a. The outer edge portion of the second low acoustic velocity region 18B overlaps not only with the outer edge portion 22A of the second part 22 of the mass-adding film 20 but also with the outer edge portion 72 of the first excitation electrode 14a.

In plan view, one of the outer edge portion 71 of the first excitation electrode 14a and the outer edge portion 81 of the second excitation electrode 14b, that is, the outer edge portion 81 is farther from the central portion of the first excitation electrode 14a than the outer edge portion of the first low acoustic velocity region 18A. One of the outer edge portion 72 of the first excitation electrode 14a and the outer edge portion 82 of the second excitation electrode 14b, that is, the outer edge portion 82 is farther from the central portion of the first excitation electrode 14a than the outer edge portion of the second low acoustic velocity region 18B.

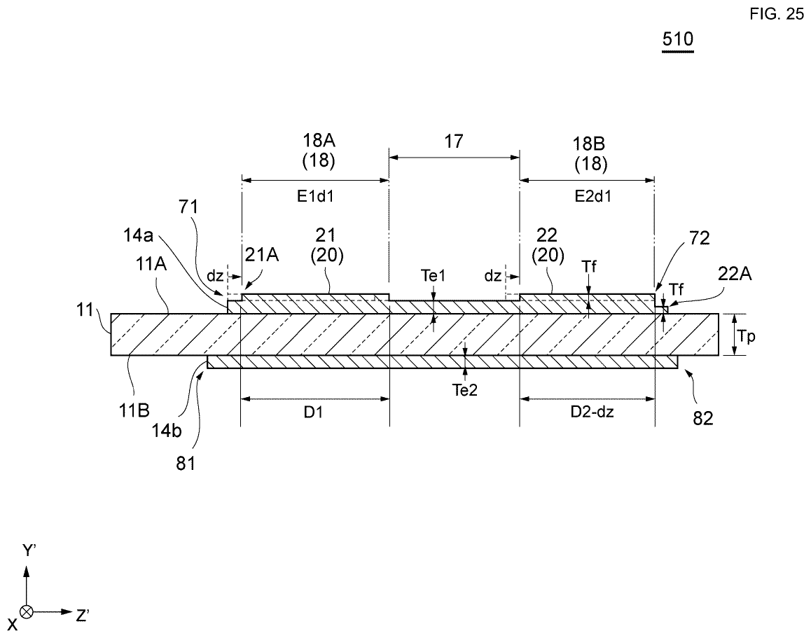

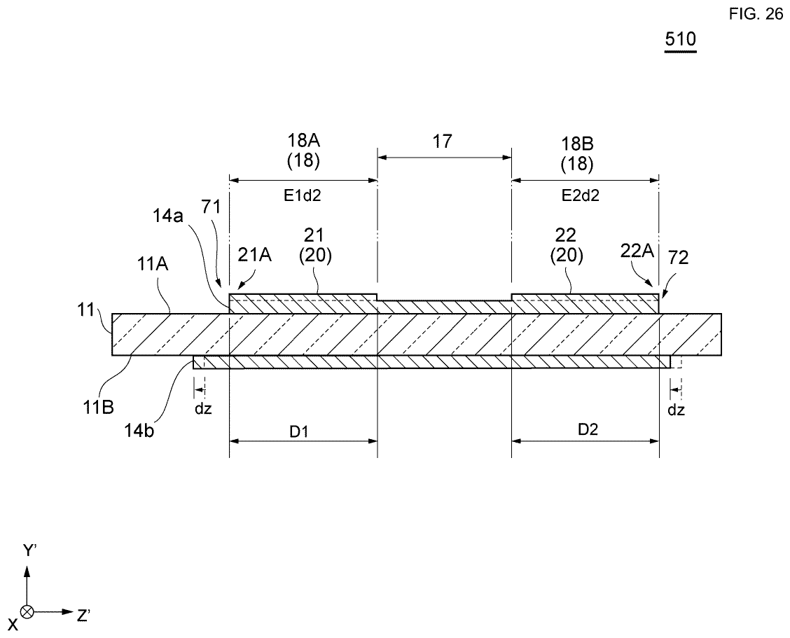

Next, the influence of positional deviation in the fifth embodiment will be described with reference to FIGS. 25 and 26. FIGS. 25 and 26 are views for describing the influence of positional deviation in the fifth embodiment. FIG. 25 is a cross-sectional view of the quartz crystal resonator 510 in a case where the mass-adding film 20 deviates by dz in the positive Z′ axis direction. FIG. 26 is a cross-sectional view of the quartz crystal resonator 510 in a case where the second excitation electrode 14b deviates by dz in the negative Z′ axis direction.

As shown in FIG. 25, in a case where the mass-adding film 20 deviates by dz in the positive Z′ axis direction, in plan view, the outer edge portion 22A of the second part 22 of the mass-adding film 20 is positioned between the outer edge portion 72 of the first excitation electrode 14a and the outer edge portion 82 of the second excitation electrode 14b. The outer edge portion 71 of the first excitation electrode 14a is positioned between the outer edge portion 21A of the first part 21 of the mass-adding film 20 and the outer edge portion 81 of the second excitation electrode 14b. The second part 22 of the mass-adding film 20 extends from the first excitation electrode 14a to the positive Z′ axis direction side by the amount of deviation dz. Therefore, the region where the first excitation electrode 14a, the second excitation electrode 14b, and the second part 22 of the mass-adding film 20 overlap with each other is reduced by the amount of deviation dz. That is, the length E2d1 is represented by E2d1=E2−dz=D2−dz. Furthermore, the area of the region where the first excitation electrode 14a, the second excitation electrode 14b, and the first part 21 of the mass-adding film 20 overlap with each other does not change. That is, the length E1d1 is represented by E1d1=E1=D1. Therefore, in a case where the mass-adding film 20 deviates by dz in the positive Z′ axis direction in the present embodiment, the balance of the lengths of the first low acoustic velocity region 18A and the second low acoustic velocity region 18B in the Z′ axis direction changes, and the relationship of E2d1<E1d1 is established. When D1=D2 in the present embodiment, in a case where the mass-adding film 20 deviates by dz in the positive Z′ axis direction, the difference in length between the first low acoustic velocity region 18A and the second low acoustic velocity region 18B in the Z′ axis direction is dz. On the other hand, in a case where the configuration in which the outer edge portion of the mass-adding film, the outer edge portion of the first excitation electrode, and the outer edge portion of the second excitation electrode overlap with each other is adopted as Comparative Example, the difference in length of the first low acoustic velocity region and the second low acoustic velocity region in the Z′ axis direction in a case where the mass-adding film deviates by dz in the positive Z′ axis direction in the Comparative Example is dz. Therefore, the deterioration of the electromechanical coupling coefficient k in a case where the positional deviation occurs in the mass-adding film 20 in the present embodiment is the same as the deterioration of the electromechanical coupling coefficient k in a case where the positional deviation occurs in the mass-adding film in Comparative example.

As shown in FIG. 26, in a case where the second excitation electrode 14b deviates by dz in the negative Z′ axis direction, the length E1d2 does not change from the length E1. That is, E1d2=E1=D1 is established. In addition, the length E2d2 does not change from the length E2. That is, the length E2d2 is represented by E2d2=E2=D2. Therefore, the balance of the lengths of the first low acoustic velocity region 18A and the second low acoustic velocity region 18B in the Z′ axis direction does not change, and the relationship of E1d2=E2d2 is established. Meanwhile, in Comparative Example, in a case where the second excitation electrode deviates by dz in the negative Z′ axis direction, the difference in length between the first low acoustic velocity region and the second low acoustic velocity region in the Z′ axis direction is dz. Therefore, the deterioration of the electromechanical coupling coefficient k in a case where the positional deviation occurs in the second excitation electrode in the present embodiment is suppressed more than the deterioration of the electromechanical coupling coefficient k in a case where the positional deviation occurs in the second excitation electrode in Comparative Example. That is, even when the second excitation electrode 14b deviates by dz in the negative Z′ axis direction, the increase in k_A0 is suppressed, and the decrease in k_S0 is suppressed.

### Sixth Embodiment

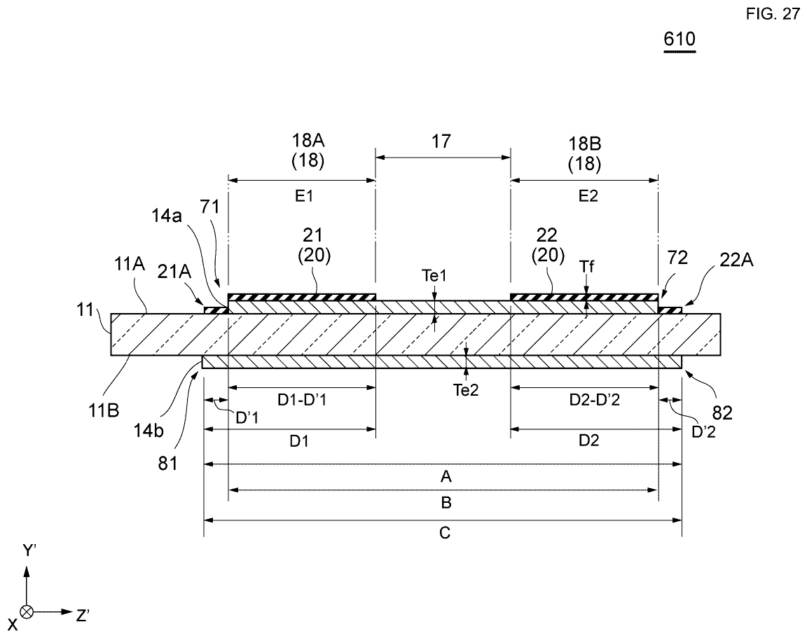

Next, a configuration of a quartz crystal resonator 610 according to a sixth embodiment will be described with reference to FIG. 27. FIG. 27 is a cross-sectional view of the quartz crystal resonator according to the sixth embodiment.

The material of the mass-adding film 20 is an insulator, for example, silicon oxide or silicon nitride. In plan view, the outer edge portion 21A of the first part 21 of the mass-adding film 20 overlaps with the outer edge portion 81 of the second excitation electrode 14b, and the outer edge portion 22A of the second part 22 of the mass-adding film 20 overlaps with the outer edge portion 82 of the second excitation electrode 14b. The outer edge portions 71 and 72 of the first excitation electrode 14a are positioned between the outer edge portion 21A and the outer edge portion 22A of the first part 21 of the mass-adding film 20. The length A is substantially equal to the length C and is greater than the length B (B<A=C). The length E1 is smaller than the length D1 (D1<E1), the length E2 is smaller than the length D2 (D2<E2), and the length E1 is substantially equal to the length E2 (E1=E2).

In plan view, the outer edge portion of the first low acoustic velocity region 18A overlaps with the outer edge portion 71 of the first excitation electrode 14a. The outer edge portion of the second low acoustic velocity region 18B overlaps with the outer edge portion 72 of the first excitation electrode 14a.

In plan view, both the outer edge portion 21A of the first part 21 of the mass-adding film 20 and the outer edge portion 81 of the second excitation electrode 14b are farther from the central portion of the first excitation electrode 14a than the outer edge portion of the first low acoustic velocity region 18A. The outer edge portion 21A and the outer edge portion 81 are farther from the central portion of the first excitation electrode 14a by approximately the same distance. Both the outer edge portion 22A of the second part 22 of the mass-adding film 20 and the outer edge portion 82 of the second excitation electrode 14b are farther from the central portion of the first excitation electrode 14a than the outer edge portion of the second low acoustic velocity region 18B. The outer edge portion 22A and the outer edge portion 82 are farther from the central portion of the first excitation electrode 14a by approximately the same distance.

When a dimension of a part of the first part 21 of the mass-adding film 20 that protrudes from the first excitation electrode 14a to the negative Z′ axis direction side in the Z′ axis direction is defined as D′1, the length E1 is represented by E1=D1−D′1. When a dimension of a part of the second part 22 of the mass-adding film 20 that protrudes from the first excitation electrode 14a to the positive Z′ axis direction side in the Z′ axis direction is represented by D′2, the length E2 is represented by E2=D2−D′2.

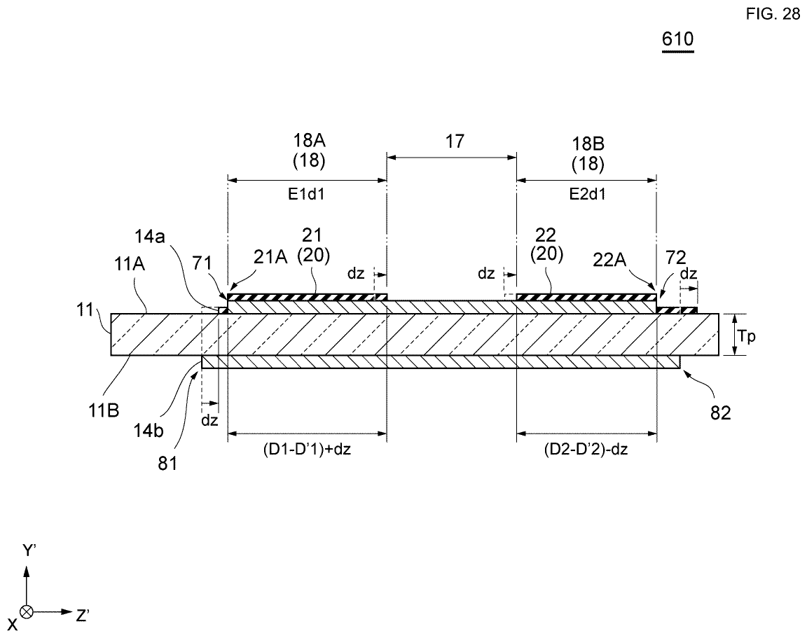

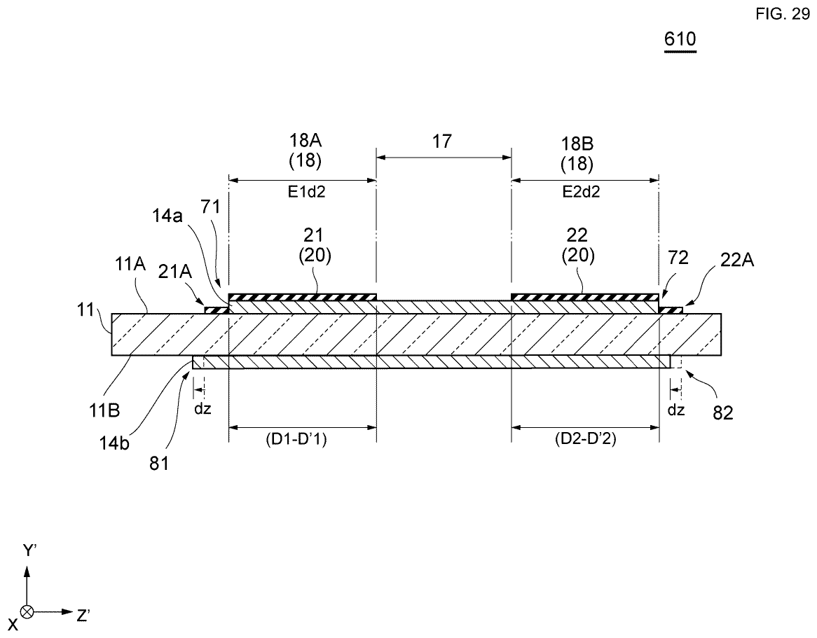

Next, the influence of positional deviation in the sixth embodiment will be described with reference to FIGS. 28 and 29. FIGS. 28 and 29 are views for describing the influence of positional deviation in the sixth embodiment. FIG. 28 is a cross-sectional view of the quartz crystal resonator 610 in a case where the mass-adding film 20 deviates by dz in the positive Z′ axis direction. FIG. 29 is a cross-sectional view of the quartz crystal resonator 610 in a case where the second excitation electrode 14b deviates by dz in the negative Z′ axis direction.

As shown in FIG. 28, in a case where the mass-adding film 20 deviates by dz in the positive Z′ axis direction, the first low acoustic velocity region 18A is enlarged by the amount of deviation dz. That is, the length E1d1 is represented by E1d1=E1+dz=(D1−D′1)+dz. In addition, the second low acoustic velocity region 18B is reduced by the amount of deviation dz. That is, the length E2d1 is represented by E2d1=E2−dz=(D2−D′2)−dz. Therefore, the balance of the lengths of the first low acoustic velocity region 18A and the second low acoustic velocity region 18B in the Z′ axis direction changes, and the relationship of E2d1<E1d1 is established. When D1=D2 and D′1=D′2, that is, E1=E2 in the present embodiment, in a case where the mass-adding film 20 deviates by dz in the positive Z′ axis direction, the difference in length between the first low acoustic velocity region 18A and the second low acoustic velocity region 18B in the Z′ axis direction is 2dz.

As shown in FIG. 29, in a case where the second excitation electrode 14b deviates by dz in the negative Z′ axis direction, the length E1d2 does not change from the length E1. That is, E1d2=E1=D1−D′1 is established. In addition, the length E2d2 does not change from the length E2. That is, E2d2=E2=D2−D′2 is established. In the present embodiment, when D1=D2 and D′1=D′2, that is, E1=E2, even in a case where the second excitation electrode 14b deviates by dz in the negative Z′ axis direction, the balance of the lengths of the first low acoustic velocity region 18A and the second low acoustic velocity region 18B in the Z′ axis direction does not change, and the relationship of E1d2=E2d2 is established. Therefore, even when the second excitation electrode 14b deviates by dz in the negative Z′ axis direction, the increase in k_A0 is suppressed, and the decrease in k_S0 is suppressed.

### Seventh Embodiment

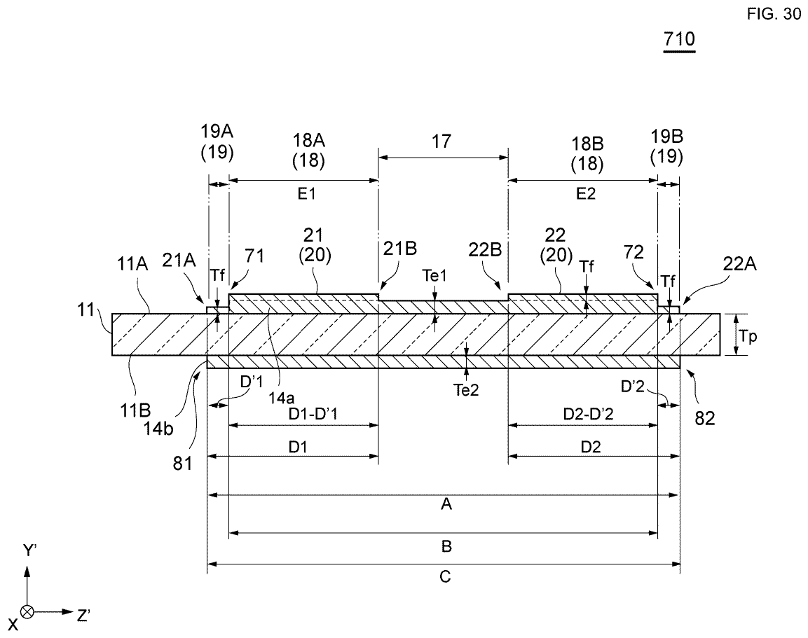

Next, a configuration of a quartz crystal resonator 710 according to a seventh embodiment will be described with reference to FIG. 30. FIG. 30 is a cross-sectional view of the quartz crystal resonator according to the seventh embodiment.

The material of the mass-adding film 20 is an electric conductor, and is, for example, the same material as that of the first excitation electrode 14a. In plan view, the outer edge portion 21A of the first part 21 of the mass-adding film 20 overlaps with the outer edge portion 81 of the second excitation electrode 14b, and the outer edge portion 22A of the second part 22 of the mass-adding film 20 overlaps with the outer edge portion 82 of the second excitation electrode 14b. The outer edge portions 71 and 72 of the first excitation electrode 14a are positioned between the outer edge portion 21A and the outer edge portion 22A of the first part 21 of the mass-adding film 20. The length A is substantially equal to the length C and is greater than the length B (B<A=C). The length E1 is smaller than the length D1 (D1<E1), the length E2 is smaller than the length D2 (D2<E2), and the length E1 is substantially equal to the length E2 (E1=E2). The length E1 is represented by E1=D1−D′1′, and the length E2 is represented by E2=D2−D′2.

In plan view, the outer edge portion of the first low acoustic velocity region 18A overlaps with the outer edge portion 71 of the first excitation electrode 14a. The outer edge portion of the second low acoustic velocity region 18B overlaps with the outer edge portion 72 of the first excitation electrode 14a.

In plan view, both the outer edge portion 21A of the first part 21 of the mass-adding film 20 and the outer edge portion 81 of the second excitation electrode 14b are farther from the central portion of the first excitation electrode 14a than the outer edge portion of the first low acoustic velocity region 18A. The outer edge portion 21A and the outer edge portion 81 are farther from the central portion of the first excitation electrode 14a by approximately the same distance. Both the outer edge portion 22A of the second part 22 of the mass-adding film 20 and the outer edge portion 82 of the second excitation electrode 14b are farther from the central portion of the first excitation electrode 14a than the outer edge portion of the second low acoustic velocity region 18B. The outer edge portion 22A and the outer edge portion 82 are farther from the central portion of the first excitation electrode 14a by approximately the same distance.

The first part 21 of the mass-adding film 20 extends from the first excitation electrode 14a to the negative Z′ direction side. The second part 22 of the mass-adding film 20 extends from the first excitation electrode 14a to the positive Z′ direction side. Since the mass-adding film 20 has the same potential as the first excitation electrode 14a, a part of the mass-adding film 20 extending from the first excitation electrode 14a functions as an excitation electrode. Therefore, a region, which is an outer side portion of the first excitation electrode 14a in plan view and in which the first part 21 of the mass-adding film 20 and the second excitation electrode 14b overlap with each other, is a first outer high acoustic velocity region 191A, and a region, which is an outer side portion of the first excitation electrode 14a and in which the second part 22 of the mass-adding film 20 and the second excitation electrode 14b overlap each other, is a second outer high acoustic velocity region 191B. The total thicknesses in the high acoustic velocity region 17 is Tp+Te1+Te2, and the total thicknesses in each of the first outer high acoustic velocity region 191A and the second outer high acoustic velocity region 191B is Tp+Tf+Te2. Therefore, when the material of the mass-adding film 20 is the same as the material of the first excitation electrode 14a and the relationship of Tf<Te1 is established, the acoustic velocities in the first outer high acoustic velocity region 191A and the second outer high acoustic velocity region 191B are greater than the acoustic velocity in the high acoustic velocity region 17. That is, the acoustic velocity of the high acoustic velocity region 17 is smaller than the acoustic velocity of the outer high acoustic velocity region 191, and the acoustic velocity of the low acoustic velocity region 18 is smaller than the acoustic velocity of the high acoustic velocity region 17. When the material of the mass-adding film 20 is the same as the material of the first excitation electrode 14a and the relationship of Tf=Te1 is established, the acoustic velocities in the first outer high acoustic velocity region 191A and the second outer high acoustic velocity region 191B are substantially equal to the acoustic velocity in the high acoustic velocity region 17. That is, the acoustic velocity of the outer high acoustic velocity region 191 is substantially equal to the acoustic velocity of the high acoustic velocity region 17 and is greater than the acoustic velocity of the low acoustic velocity region 18. When the material of the mass-adding film 20 is the same as the material of the first excitation electrode 14a and the relationship of Te1<Tf is established, the acoustic velocities in the first outer high acoustic velocity region 191A and the second outer high acoustic velocity region 191B are substantially smaller than the acoustic velocity in the high acoustic velocity region 17. That is, the acoustic velocity of the outer high acoustic velocity region 191 is smaller than the acoustic velocity of the high acoustic velocity region 17, and the acoustic velocity of the low acoustic velocity region 18 is smaller than the acoustic velocity of the outer high acoustic velocity region 191.

Furthermore, in a case where the material of the mass-adding film 20 is different from the material of the first excitation electrode 14a, even when the relationship of Tf<Te1 is established, the acoustic velocity of the outer high acoustic velocity region 191 may be lower than the acoustic velocity of the high acoustic velocity region 17. For example, in a case where the mass per unit area of the mass-adding film 20 is greater than the mass per unit area of the first excitation electrode 14a, the acoustic velocity of the outer high acoustic velocity region 191 is smaller than the acoustic velocity of the high acoustic velocity region 17. In a case where the mass per unit area of the mass-adding film 20 is equal to the mass per unit area of the first excitation electrode 14a, the acoustic velocity of the outer high acoustic velocity region 191 is equal to the acoustic velocity of the high acoustic velocity region 17. In a case where the mass per unit area of the mass-adding film 20 is smaller than the mass per unit area of the first excitation electrode 14a, the acoustic velocity of the outer high acoustic velocity region 191 is smaller than the acoustic velocity of the high acoustic velocity region 17.

In the quartz crystal resonator 610 according to the sixth embodiment and the quartz crystal resonator 710 according to the seventh embodiment, the relationship of B<A=C is established. However, when the relationship of B<C is established, the relationship of C<A may be established. That is, the relationship of B<C<A may be established.

### Eighth Embodiment

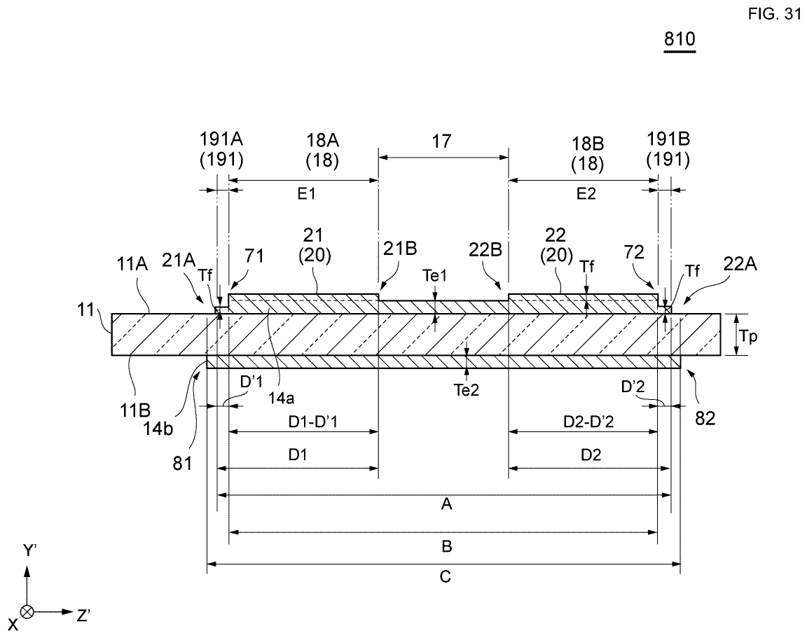

Next, a configuration of a quartz crystal resonator 810 according to an eighth embodiment will be described with reference to FIG. 31. FIG. 31 is a cross-sectional view of the quartz crystal resonator according to the eighth embodiment.

In plan view, the outer edge portion 21A of the first part 21 and the outer edge portion 22A of the second part 22 of the mass-adding film 20 are positioned between the outer edge portion 81 and the outer edge portion 82 of the second excitation electrode 14b. The outer edge portion 71 of the first excitation electrode 14a is positioned between the outer edge portion 21A of the first part 21 of the mass-adding film 20 and the outer edge portion 81 of the second excitation electrode 14b. The outer edge portion 72 of the first excitation electrode 14a is positioned between the outer edge portion 22A of the second part 22 of the mass-adding film 20 and the outer edge portion 82 of the second excitation electrode 14b. The length A is greater than the length B and is smaller than the length C (B<A<C). The length E1 is smaller than the length D1 (D1<E1), the length E2 is smaller than the length D2 (D2<E2), and the length E1 is substantially equal to the length E2 (E1=E2). The length E1 is represented by E1=D1−D′1, and the length E2 is represented by E2=D2−D′2.

In plan view, the outer edge portion of the first low acoustic velocity region 18A overlaps with the outer edge portion 71 of the first excitation electrode 14a. The outer edge portion of the second low acoustic velocity region 18B overlaps with the outer edge portion 72 of the first excitation electrode 14a.

In plan view, both the outer edge portion 21A of the first part 21 of the mass-adding film 20 and the outer edge portion 81 of the second excitation electrode 14b are farther from the central portion of the first excitation electrode 14a than the outer edge portion of the first low acoustic velocity region 18A. The outer edge portion 81 is farther from the central portion of the first excitation electrode 14a than the outer edge portion 21A. Both the outer edge portion 22A of the second part 22 of the mass-adding film 20 and the outer edge portion 82 of the second excitation electrode 14b are farther from the central portion of the first excitation electrode 14a than the outer edge portion of the second low acoustic velocity region 18B. The outer edge portion 82 is farther from the central portion of the first excitation electrode 14a than the outer edge portion 22A by approximately the same distance.

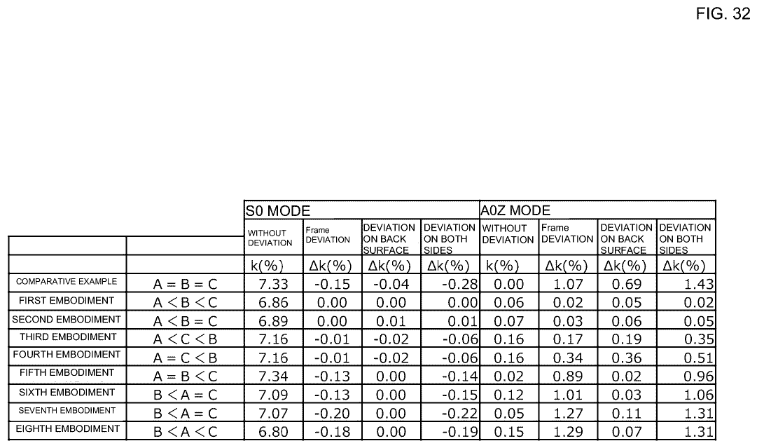

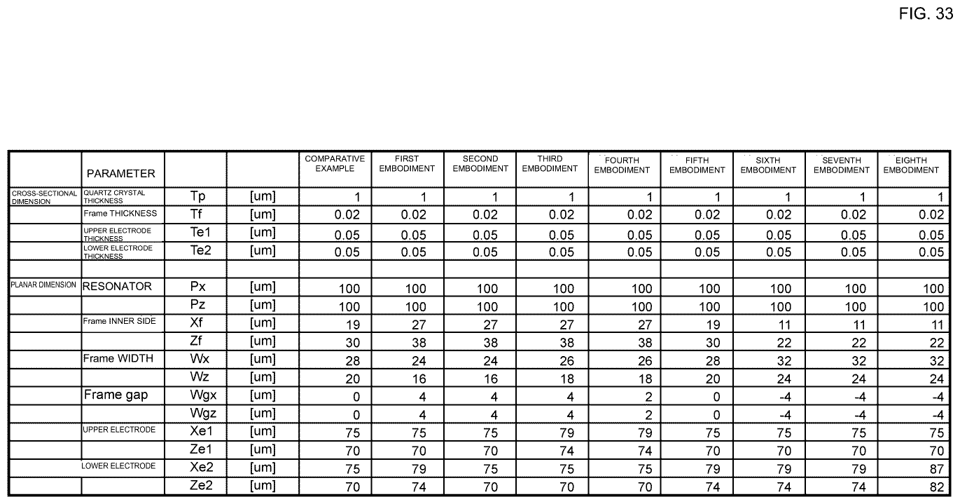

The change in the electromechanical coupling coefficient k in Comparative Example and Examples based on the first to eighth embodiments will be described with reference to FIGS. 32 and 33. FIG. 32 is a table showing simulation results of Comparative Example and Examples based on the first to eighth embodiments. FIG. 33 is a table showing simulation conditions of Comparative Example and Examples based on the first to eighth embodiments.

### Comparative Example

A=B=C
Tp=1.00 μm
Tf=0.02 μm
Te1=Te2=0.05 μm
Px=Pz=100 μm
Xf=19 μm
Zf=30 μm
Wx=28 μm
Wz=20 μm
Wgx=Wgz=0 μm
Xe1=75 μm
Ze1=70 μm
Xe2=75 μm
Ze2=70 μm

### Example Based on First Embodiment

A<B<C
Tp=1.00 μm
Tf=0.02 μm
Te1=Te2=0.05 μm
Px=Pz=100 μm
Xf=27 μm
Zf=38 μm
Wx=24 μm
Wz=16 μm
Wgx=Wgz=4 μm
Xe1=75 μm
Ze1=70 μm
Xe2=79 μm
Ze2=74 μm

### Example Based on Second Embodiment

A<B=C
Tp=1.00 μm
Tf=0.02 μm
Te1=Te2=0.05 μm
Px=Pz=100 μm
Xf=27 μm
Zf=38 μm
Wx=24 μm
Wz=16 μm
Wgx=Wgz=4 μm
Xe1=75 μm
Ze1=70 μm
Xe2=75 μm
Ze2=70 μm

### Example Based on Third Embodiment

A<C<B
Tp=1.00 μm
Tf=0.02 μm
Te1=Te2=0.05 μm
Px=Pz=100 μm
Xf=27 μm
Zf=38 μm
Wx=26 μm
Wz=18 μm
Wgx=Wgz=4 μm
Xe1=79 μm
Ze2=74 μm
Xe2=75 μm
Ze2=70 μm

### Example Based on Fourth Embodiment

A=C<B
Tp=1.00 μm
Tf=0.02 μm
Te1=Te2=0.05 μm
Px=Pz=100 μm
Xf=27 μm
Zf=38 μm
Wx=26 μm
Wz=18 μm
Wgx=Wgz=2 μm
Xe1=79 μm
Ze2=74 μm
Xe2=75 μm
Ze2=70 μm

### Example Based on Fifth Embodiment

A=B<C
Tp=1.00 μm
Tf=0.02 μm
Te1=Te2=0.05 μm
Px=Pz=100 μm
Xf=19 μm
Zf=30 μm
Wx=28 μm
Wz=20 μm
Wgx=Wgz=0 μm
Xe1=75 μm
Ze2=70 μm
Xe2=79 μm
Ze2=74 μm

### Example Based on Sixth Embodiment

B<A=C
Tp=1.00 μm
Tf=0.02 μm
Te1=Te2=0.05 μm
Px=Pz=100 μm
Xf=11 μm
Zf=22 μm
Wx=32 μm
Wz=24 μm
Wgx=Wgz=−4 μm
Xe1=75 μm
Ze2=70 μm
Xe2=79 μm
Ze2=74 μm

### Example Based on Seventh Embodiment

B<A=C
Tp=1.00 μm
Tf=0.02 μm
Te1=Te2=0.05 μm
Px=Pz=100 μm
Xf=11 μm
Zf=22 μm
Wx=32 μm
Wz=24 μm
Wgx=Wgz=−4 μm
Xe1=75 μm
Ze2=70 μm
Xe2=79 μm
Ze2=74 μm

### Example Based on Eighth Embodiment

B<A<C
Tp=1.00 μm
Tf=0.02 μm
Te1=Te2=0.05 μm
Px=Pz=100 μm
Xf=11 μm
Zf=22 μm
Wx=32 μm
Wz=24 μm
Wgx=Wgz=−4 μm
Xe1=75 μm
Ze2=70 μm
Xe2=87 μm
Ze2=82 μm

“Frame deviation” in the table of FIG. 32 means a state where the position of the mass-adding film 20 deviates with respect to the positions of the first excitation electrode 14a and the second excitation electrode 14b. The “deviation on back surface” means a state where the position of the second excitation electrode 14b deviates with respect to the positions of the mass-adding film 20 and the first excitation electrode 14a. The “deviation on both sides” means a state where the position of the mass-adding film 20 deviates with respect to the position of the first excitation electrode 14a, and the position of the second excitation electrode 14b deviates with respect to the position of the first excitation electrode 14a in a direction opposite to the positional deviation of the position of the mass-adding film 20.

In Comparative Example, the amount of change Δk of k in the frame deviation of the S0 mode is −0.15%, the amount of change Δk of k in the deviation on back surface of the S0 mode is −0.04%, and the amount of change Δk of k in deviation on both sides of the S0 mode is −0.28%. In Comparative Example, the amount of change Δk of k in the frame deviation of the A0Z mode is 1.07%, the amount of change Δk of k in the deviation on back surface of the A0Z mode is 0.69%, and the amount of change Δk of k in deviation on both sides of the A0Z mode is 1.43%.

In Example based on the first embodiment, the amount of change Δk of k in the frame deviation of the S0 mode is 0.00%, the amount of change Δk of k in the deviation on back surface of the S0 mode is 0.00%, and the amount of change Δk of k in deviation on both sides of the S0 mode is 0.00%. The Δk of the S0 mode in Example based on the first embodiment is smaller than the Δk of the S0 mode in Comparative Example. That is, in Example based on the first embodiment, the decrease in k of the S0 mode due to the positional deviation is suppressed.

In Example based on the first embodiment, the amount of change Δk of k in the frame deviation of the A0Z mode is 0.02%, the amount of change Δk of k in the deviation on back surface of the A0Z mode is 0.05%, and the amount of change Δk of k in deviation on both sides of the A0Z mode is 0.02%. The Δk of the A0Z mode in Example based on the first embodiment is smaller than the Δk of the A0Z mode in Comparative Example. That is, in Example based on the first embodiment, the increase in k of the A0Z mode due to the positional deviation is suppressed.

In Example based on the second embodiment, the amount of change Δk of k in the frame deviation of the S0 mode is 0.00%, the amount of change Δk of k in the deviation on back surface of the S0 mode is 0.01%, and the amount of change Δk of k in deviation on both sides of the S0 mode is 0.01%. The amount of change Δk of k in the frame deviation of the A0Z mode is 0.03%, the amount of change Δk of k in the deviation on back surface of the A0Z mode is 0.06%, and the amount of change Δk of k in deviation on both sides of the A0Z mode is 0.05%.

In Example based on the third embodiment, the amount of change Δk of k in the frame deviation of the S0 mode is −0.01%, the amount of change Δk of k in the deviation on back surface of the S0 mode is −0.02%, and the amount of change Δk of k in deviation on both sides of the S0 mode is −0.06%. The amount of change Δk of k in the frame deviation of the A0Z mode is 0.17%, the amount of change Δk of k in the deviation on back surface of the A0Z mode is 0.19%, and the amount of change Δk of k in deviation on both sides of the A0Z mode is 0.35%.

In Example based on the fourth embodiment, the amount of change Δk of k in the frame deviation of the S0 mode is −0.01%, the amount of change Δk of k in the deviation on back surface of the S0 mode is −0.02%, and the amount of change Δk of k in deviation on both sides of the S0 mode is −0.06%. The amount of change Δk of k in the frame deviation of the A0Z mode is 0.34%, the amount of change Δk of k in the deviation on back surface of the A0Z mode is 0.36%, and the amount of change Δk of k in deviation on both sides of the A0Z mode is 0.51%.

As in Example based on the first embodiment, in Examples based on the second to fourth embodiments, the decrease in k of the S0 mode due to the positional deviation is suppressed. As in Example based on the first embodiment, in Example based on the second embodiment, the increase in k of the A0Z mode due to the positional deviation is suppressed.

In Example based on the fifth embodiment, the amount of change Δk of k in the frame deviation of the S0 mode is −0.13%, the amount of change Δk of k in the deviation on back surface of the S0 mode is −0.00%, and the amount of change Δk of k in deviation on both sides of the S0 mode is −0.14%. The amount of change Δk of k in the frame deviation of the A0Z mode is 0.89%, the amount of change Δk of k in the deviation on back surface of the A0Z mode is 0.02%, and the amount of change Δk of k in deviation on both sides of the A0Z mode is 0.96%.

In Example based on the sixth embodiment, the amount of change Δk of k in the frame deviation of the S0 mode is −0.13%, the amount of change Δk of k in the deviation on back surface of the S0 mode is 0.00%, and the amount of change Δk of k in deviation on both sides of the S0 mode is −0.15%. The amount of change Δk of k in the frame deviation of the A0Z mode is 1.01%, the amount of change Δk of k in the deviation on back surface of the A0Z mode is 0.03%, and the amount of change Δk of k in deviation on both sides of the A0Z mode is 1.06%.

In Examples based on the fifth and sixth embodiments, Δk of the S0 mode and Δk of the A0Z mode in the frame deviation are substantially equal to Δk of the S0 mode and Δk of the A0Z mode in Comparative Example. In Examples based on the fifth and sixth embodiments, the decrease in Δk of the S0 mode in the deviation on back surface and the deviation on both sides is suppressed, and the increase in Δk of the A0Z mode in the deviation on back surface and the deviation on both sides is suppressed.

In Example based on the seventh embodiment, the amount of change Δk of k in the frame deviation of the S0 mode is −0.20%, the amount of change Δk of k in the deviation on back surface of the S0 mode is 0.00%, and the amount of change Δk of k in deviation on both sides of the S0 mode is −0.22%. The amount of change Δk of k in the frame deviation of the A0Z mode is 1.27%, the amount of change Δk of k in the deviation on back surface of the A0Z mode is 0.11%, and the amount of change Δk of k in deviation on both sides of the A0Z mode is 1.31%.

In Example based on the eighth embodiment, the amount of change Δk of k in the frame deviation of the S0 mode is −0.18%, the amount of change Δk of k in the deviation on back surface of the S0 mode is 0.00%, and the amount of change Δk of k in deviation on both sides of the S0 mode is −0.19%. The amount of change Δk of k in the frame deviation of the A0Z mode is 1.29%, the amount of change Δk of k in the deviation on back surface of the A0Z mode is 0.07%, and the amount of change Δk of k in deviation on both sides of the A0Z mode is 1.31%.

In Examples based on the seventh and eighth embodiments, Δk of the S0 mode and Δk of the A0Z mode in the frame deviation have slightly deteriorated compared to Δk of the S0 mode and Δk of the A0Z mode in Comparative Example. However, in Examples based on the seventh and eighth embodiments, the decrease in Δk of the S0 mode in the deviation on back surface and the deviation on both sides is suppressed, and the increase in Δk of the A0Z mode in the deviation on back surface and the deviation on both sides is suppressed.

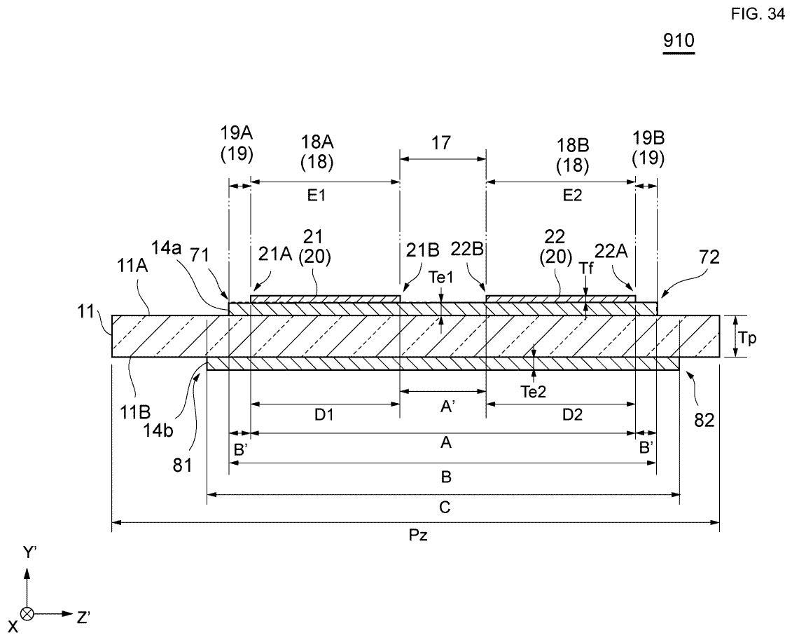

Next, a configuration of a quartz crystal resonator 910 according to a ninth embodiment will be described with reference to FIG. 34. FIG. 34 is a cross-sectional view of the quartz crystal resonator according to the ninth embodiment.

In the present embodiment, the mass-adding film 20 is provided with a metal having a material different from that of the first excitation electrode 14a. From the viewpoint of efficiently adding mass and reducing the acoustic velocity in the low acoustic velocity region 18, it is desirable that the specific gravity of the mass-adding film 20 is greater than the specific gravity of the first excitation electrode 14a. As a result, it is possible to shorten the film forming process of the mass-adding film 20 and improve the manufacturing efficiency.

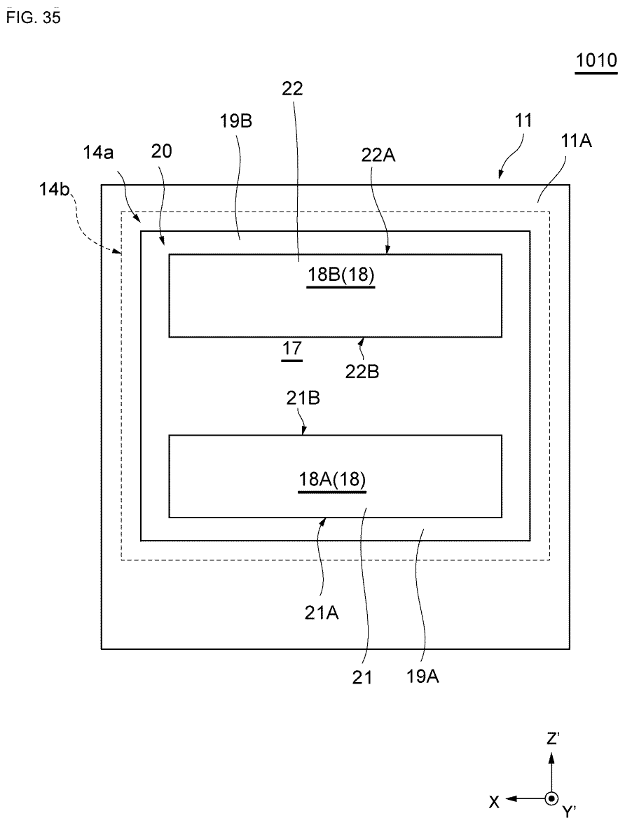

Next, a configuration of a quartz crystal resonator 1010 according to a tenth embodiment will be described with reference to FIG. 35. FIG. 35 is a plan view of the quartz crystal resonator according to the tenth embodiment.

The third part 23 and the fourth part 24 of the mass-adding film 20 are omitted. The first part 21 and the second part 22 of the mass-adding film 20 are separated from each other and provided in a strip shape extending in the X axis direction.

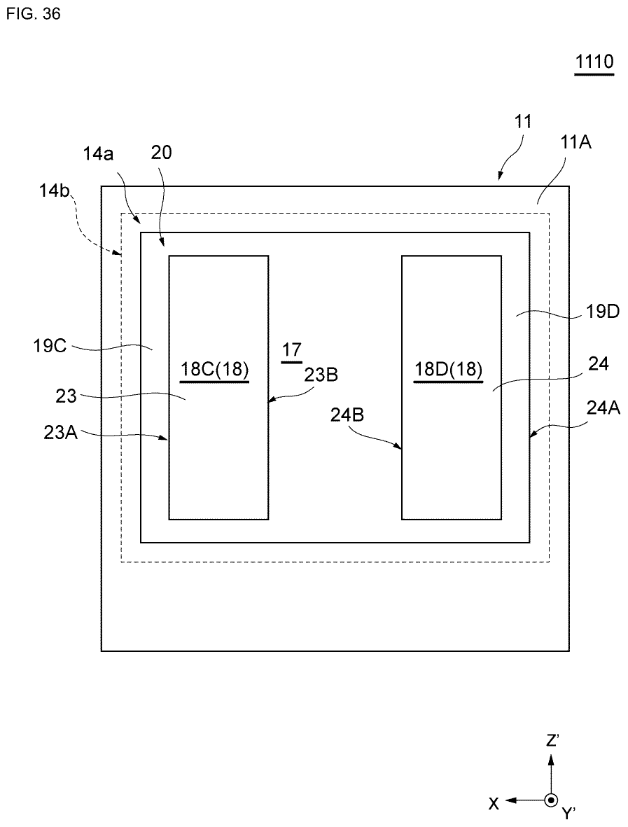

Next, a configuration of a quartz crystal resonator 1110 according to an eleventh embodiment will be described with reference to FIG. 36. FIG. 36 is a plan view of the quartz crystal resonator according to the eleventh embodiment.

The first part 21 and the second part 22 of the mass-adding film 20 are omitted. The third part 23 and the fourth part 24 of the mass-adding film 20 are separated from each other and provided in a strip shape extending in the Z′ axis direction.

Hereinafter, a part or all of the embodiments of the present disclosure will be appended below. The present disclosure is not limited to the following addendum.

<1> A piezoelectric vibration element including: a piezoelectric substrate having a first main surface that extends in a first direction and a second direction intersecting the first direction, and a second main surface facing the first main surface; a first excitation electrode on the first main surface of the piezoelectric substrate, wherein the first excitation electrode includes a first outer edge portion on a side in the first direction with respect to a central portion thereof and a second outer edge portion on a second side in the first direction with respect to the central portion, in a plan view of the piezoelectric vibration element; a second excitation electrode on the second main surface of the piezoelectric substrate, wherein the second excitation electrode includes a third outer edge portion on the first side in the first direction with respect to the central portion and a fourth outer edge portion on the second side in the first direction with respect to the central portion, in the plan view; and a mass-adding film at least a part of which overlaps with the first excitation electrode, wherein the mass-adding film includes a first part and a second part which do not overlap the central portion of the first excitation electrode, wherein the first part extends along the first outer edge portion, and the second part extends along the second outer edge portion, and when a first region where the piezoelectric substrate, the first excitation electrode, and the second excitation electrode overlap with each other is defined as a high acoustic velocity region, a second region where the piezoelectric substrate, the first excitation electrode, and the second excitation electrode overlap with the first part of the mass-adding film is defined as a first low acoustic velocity region, and a third region where the piezoelectric substrate, the first excitation electrode, and the second excitation electrode overlap with the second part of the mass-adding film is defined as a second low acoustic velocity region, in the plan view: the third outer edge portion is farther from the central portion than the first low acoustic velocity region, and the fourth outer edge portion is farther from the central portion than the second low acoustic velocity region.

<2> A piezoelectric vibration element including: a piezoelectric substrate having a first main surface that extends in a first direction and a second direction intersecting the first direction, and a second main surface facing the first main surface; a first excitation electrode on the first main surface of the piezoelectric substrate, wherein the first excitation electrode includes a first outer edge portion on a side in the first direction with respect to a central portion thereof and a second outer edge portion on a second side in the first direction with respect to the central portion, in a plan view of the piezoelectric vibration element; a second excitation electrode on the second main surface of the piezoelectric substrate, wherein the second excitation electrode includes a third outer edge portion on the first side in the first direction with respect to the central portion and a fourth outer edge portion on the second side in the first direction with respect to the central portion, in the plan view; and a mass-adding film at least a part of which overlaps with the first excitation electrode, wherein the mass-adding film includes a first part and a second part which do not overlap the central portion of the first excitation electrode, wherein the first part extends along the first outer edge portion, and the second part extends along the second outer edge portion, and when a first region where the piezoelectric substrate, the first excitation electrode, and the second excitation electrode overlap with each other is defined as a high acoustic velocity region, a second region where the piezoelectric substrate, the first excitation electrode, and the second excitation electrode overlap with the first part of the mass-adding film is defined as a first low acoustic velocity region, and a third region where the piezoelectric substrate, the first excitation electrode, and the second excitation electrode overlap with the second part of the mass-adding film is defined as a second low acoustic velocity region, and when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C: A=C<B, in the plan view, an outer edge portion of the first low acoustic velocity region opposite to the second low acoustic velocity region and an outer edge of the second low acoustic velocity region opposite to the first low acoustic velocity region overlap with the first excitation electrode, and in the plan view, the third outer edge portion and the fourth outer edge portion of the second excitation electrode overlap with the first excitation electrode.

<3> The piezoelectric vibration element according to <1>, in which in plan view, the first outer edge portion and the second outer edge portion overlap with the second excitation electrode.

<4> The piezoelectric vibration element according to any one of <1> to <3>, in which when a dimension in the first direction between an outer edge portion of the first low acoustic velocity region opposite to the central portion and an outer edge portion of the second low acoustic velocity region opposite to the central portion is defined as E, and a distance in the first direction between an outer edge portion proximal to the first low acoustic velocity region and an outer edge portion proximal to the second low acoustic velocity region in the high acoustic velocity region is defined as E′, a dimension of the first low acoustic velocity region in the first direction and a dimension of the second low acoustic velocity region in the first direction are (1+0.04)×(E−E′)/2.

<5> The piezoelectric vibration element according to <1>, in which when a dimension in the first direction between an end portion of the first part opposite to the second part and an end portion of the second part opposite to the first part in the mass-adding film is defined as A, and a dimension of the first excitation electrode in the first direction is defined as B, A<B.

<6> The piezoelectric vibration element according to <5>, in which when a dimension of the second excitation electrode in the first direction is defined as C, A<B<C.

<7> The piezoelectric vibration element according to <5>, in which when a dimension of the second excitation electrode in the first direction is defined as C, A<B=C.

<8> The piezoelectric vibration element according to <5>, in which when a dimension of the second excitation electrode in the first direction is defined as C, A=C<B.

<9> The piezoelectric vibration element according to <5>, in which when a dimension of the second excitation electrode in the first direction is defined as C, A<C<B.

<10> The piezoelectric vibration element according to <1>, in which when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C, A=B<C.

<11> The piezoelectric vibration element according to <1>, in which when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C, B<A=C.

<12> The piezoelectric vibration element according to <1>, in which when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C, B<A<C.

<13> The piezoelectric vibration element according to any one of <1> to <12>, in which a material of the mass-adding film is an electric conductor.

<14> The piezoelectric vibration element according to any one of <1> to <12>, in which a material of the mass-adding film is an insulator.

<15> The piezoelectric vibration element according to any one of <1> to <14>, in which when a distance in the first direction between an end portion of the first part opposite to the second part and an end portion of the second part opposite to the first part in the mass-adding film is defined as A′, and a dimension of the first excitation electrode in the first direction is defined as B, A′/B≤0.5.

<16> The piezoelectric vibration element according to <15>, in which 0.05≤A′/B.

<17> The piezoelectric vibration element according to <1>, in which a distance in the first direction between an outer edge portion positioned on the first side of the first part of the mass-adding film and the first outer edge portion of the first excitation electrode, and a distance in the first direction between an outer edge portion positioned on the second side of the second part of the mass-adding film and the second outer edge portion of the first excitation electrode are 0.5 μm or greater.

<18> The piezoelectric vibration element according to <17>, in which the distance in the first direction between the outer edge portion positioned on the first side of the first part of the mass-adding film and the first outer edge portion of the first excitation electrode, and the distance in the first direction between the outer edge portion positioned on the second side of the second part of the mass-adding film and the second outer edge portion of the first excitation electrode are 8 μm or less.

<19> The piezoelectric vibration element according to <1>, in which when a dimension of the first excitation electrode in the first direction is defined as B, and a dimension of the second excitation electrode in the first direction is defined as C, 3 μm≤C−B.

<20> The piezoelectric vibration element according to <19>, in which when the dimension of the first excitation electrode in the first direction is defined as B, and the dimension of the second excitation electrode in the first direction is defined as C, C−B≤8 μm.

<21> The piezoelectric vibration element according to any one of <1> to <20>, in which the mass-adding film includes a third part and a fourth part which do not overlap the central portion of the first excitation electrode, the first excitation electrode includes a fifth outer edge portion positioned on a third side in the second direction with respect to the central portion and a sixth outer edge portion positioned on a fourth side in the second direction with respect to the central portion, in the plan view, the second excitation electrode includes a seventh outer edge portion positioned on the third side in the second direction with respect to the central portion and an eighth outer edge portion positioned on the fourth side in the second direction with respect to the central portion, in the plan view, the third part extends along the fifth outer edge portion, the fourth part extends along the sixth outer edge portion, and when a fourth region where the piezoelectric substrate, the first excitation electrode, and the second excitation electrode overlap with the third part of the mass-adding film is defined as a third low acoustic velocity region, and a fifth region where the piezoelectric substrate, the first excitation electrode, and the second excitation electrode overlap with the fourth part of the mass-adding film is defined as a fourth low acoustic velocity region, in the plan view: the seventh outer edge portion is farther from the central portion than the third low acoustic velocity region, and the eighth outer edge portion is farther from the central portion than the fourth low acoustic velocity region.

<22> The piezoelectric vibration element according to any one of <1> to <21>, in which the mass-adding film includes a third part and a fourth part which do not overlap the central portion of the first excitation electrode, the first excitation electrode includes a fifth outer edge portion on a third side in the second direction with respect to the central portion and a sixth outer edge portion on a fourth side in the second direction with respect to the central portion, in the plan view, the second excitation electrode includes a seventh outer edge portion on the third side in the second direction with respect to the central portion and an eighth outer edge portion on the fourth side in the second direction with respect to the central portion, in the plan view, the third part extends along the fifth outer edge portion, the fourth part extends along the sixth outer edge portion, and a fourth region where the piezoelectric substrate, the first excitation electrode, and the second excitation electrode overlap with the third part of the mass-adding film is defined as a third low acoustic velocity region, and a fifth region where the piezoelectric substrate, the first excitation electrode, and the second excitation electrode further overlap with the fourth part of the mass-adding film is defined as a fourth low acoustic velocity region, a dimension in the second direction between an end portion of the third part opposite to the fourth part and an end portion of the fourth part opposite to the third part in the mass-adding film is equal to a dimension of the second excitation electrode in the second direction and is smaller than a dimension of the first excitation electrode in the second direction, in the plan view, an outer edge portion of the third low acoustic velocity region opposite to the fourth low acoustic velocity region and an outer edge portion of the fourth low acoustic velocity region opposite to the third low acoustic velocity region overlap with the first excitation electrode, and in the plan view, the seventh outer edge portion and the eighth outer edge portion of the second excitation electrode overlap with the first excitation electrode.

<23> The piezoelectric vibration element according to any one of <1> to <22>, in which the first excitation electrode includes a fifth outer edge portion positioned on a third side in the second direction with respect to the central portion and a sixth outer edge portion positioned on a fourth side in the second direction with respect to the central portion, in the plan view, and in the plan view, the fifth outer edge portion and the sixth outer edge portion overlap with the second excitation electrode.

<24> The piezoelectric vibration element according to any one of <1> to <23>, in which the piezoelectric substrate is a quartz crystal element.

<25> The piezoelectric vibration element according to <24>, in which cut-angles of the quartz crystal element is an AT cut, a BT cut, or an ST cut.

<26> The piezoelectric vibration element according to any one of <1> to <25>, in which a main vibration mode of the piezoelectric vibration element is a thickness shear vibration.

The embodiment according to the present disclosure is not limited to a quartz crystal resonator unit, but can be also applied to another piezoelectric resonator unit. As a piezoelectric substrate that is preferably used for the piezoelectric resonator unit according to the present embodiment, for example, a piezoelectric ceramic such as lead zirconate titanate (PZT) or aluminum nitride, a piezoelectric single crystal such as lithium niobate or lithium tantalate, and the like are used. However, the material of the piezoelectric substrate is not limited thereto, and can be selected as appropriate.

The embodiments according to the present disclosure are not particularly limited, and can be applied as appropriate to any device that performs conversion between electrical energy and mechanical energy using a piezoelectric effect, such as a timing device, a sound generator, an oscillator, or a load sensor.

As described above, according to one aspect of the present disclosure, it is possible to provide a piezoelectric vibration element capable of suppressing deterioration in electromechanical coupling coefficient.

The embodiments described above are for facilitating the understanding of the present disclosure, and are not intended to be construed as limiting the present disclosure. The present disclosure may be modified/improved without departing from the concept of the present disclosure, and the present disclosure also includes equivalents thereof. That is, the scope of the present disclosure includes designs obtained by appropriately changing the embodiments and/or the modification examples by those skilled in the art as long as the designs have the characteristics of the present disclosure. For example, each component included in the embodiments and/or the modification examples, arrangement, a material, a condition, a shape, a size, and the like of the component are not limited to those illustrated, and can be changed as appropriate. In addition, the embodiments and the modification examples are merely examples, and it goes without saying that partial substitutions or combinations of the configurations illustrated in the different embodiments and/or modification examples can be made, and substitutions or combinations are also included within the scope of the present disclosure as long as the substitutions or combinations include the characteristics of the present disclosure.

### REFERENCE SIGNS LIST

100 CRYSTAL OSCILLATOR
1 QUARTZ CRYSTAL RESONATOR UNIT
10 QUARTZ CRYSTAL RESONATOR
11 QUARTZ CRYSTAL ELEMENT
11A UPPER SURFACE
11B LOWER SURFACE
14a FIRST EXCITATION ELECTRODE
14b SECOND EXCITATION ELECTRODE
17 HIGH ACOUSTIC VELOCITY REGION
18 LOW ACOUSTIC VELOCITY REGION
18A FIRST LOW ACOUSTIC VELOCITY REGION
18B SECOND LOW ACOUSTIC VELOCITY REGION
18C THIRD LOW ACOUSTIC VELOCITY REGION
18D FOURTH LOW ACOUSTIC VELOCITY REGION
19 OUTER HIGH ACOUSTIC VELOCITY REGION
19A FIRST OUTER HIGH ACOUSTIC VELOCITY REGION
19B SECOND OUTER HIGH ACOUSTIC VELOCITY REGION
19C THIRD OUTER HIGH ACOUSTIC VELOCITY REGION
19D FOURTH OUTER HIGH ACOUSTIC VELOCITY REGION
20 MASS-ADDING FILM
21 FIRST PART
21A OUTER EDGE PORTION
21B INNER EDGE PORTION
22 SECOND PART
22A OUTER EDGE PORTION
22B INNER EDGE PORTION
23 THIRD PART
23A OUTER EDGE PORTION
23B INNER EDGE PORTION
24 FOURTH PART
24A OUTER EDGE PORTION
24B INNER EDGE PORTION
71, 72 OUTER EDGE PORTION
81, 82 OUTER EDGE PORTION

1. A piezoelectric vibration element comprising:
a piezoelectric substrate having a first main surface that extends in a first direction and a second direction intersecting the first direction, and a second main surface facing the first main surface;
a first excitation electrode on the first main surface of the piezoelectric substrate, wherein the first excitation electrode includes a first outer edge portion on a side in the first direction with respect to a central portion thereof and a second outer edge portion on a second side in the first direction with respect to the central portion, in a plan view of the piezoelectric vibration element;
a second excitation electrode on the second main surface of the piezoelectric substrate, wherein the second excitation electrode includes a third outer edge portion on the first side in the first direction with respect to the central portion and a fourth outer edge portion on the second side in the first direction with respect to the central portion, in the plan view; and
a mass-adding film at least a part of which overlaps with the first excitation electrode, wherein the mass-adding film includes a first part and a second part which do not overlap the central portion of the first excitation electrode, wherein the first part extends along the first outer edge portion, and the second part extends along the second outer edge portion, and
when a first region where the piezoelectric substrate, the first excitation electrode, and the second excitation electrode overlap with each other is defined as a high acoustic velocity region, a second region where the piezoelectric substrate, the first excitation electrode, and the second excitation electrode overlap with the first part of the mass-adding film is defined as a first low acoustic velocity region, and a third region where the piezoelectric substrate, the first excitation electrode, and the second excitation electrode overlap with the second part of the mass-adding film is defined as a second low acoustic velocity region, in the plan view:
the third outer edge portion is farther from the central portion than the first low acoustic velocity region, and
the fourth outer edge portion is farther from the central portion than the second low acoustic velocity region.

2. A piezoelectric vibration element comprising:
a piezoelectric substrate having a first main surface that extends in a first direction and a second direction intersecting the first direction, and a second main surface facing the first main surface;
a first excitation electrode on the first main surface of the piezoelectric substrate, wherein the first excitation electrode includes a first outer edge portion on a side in the first direction with respect to a central portion thereof and a second outer edge portion on a second side in the first direction with respect to the central portion, in a plan view of the piezoelectric vibration element;
a second excitation electrode on the second main surface of the piezoelectric substrate, wherein the second excitation electrode includes a third outer edge portion on the first side in the first direction with respect to the central portion and a fourth outer edge portion on the second side in the first direction with respect to the central portion, in the plan view; and
a mass-adding film at least a part of which overlaps with the first excitation electrode, wherein the mass-adding film includes a first part and a second part which do not overlap the central portion of the first excitation electrode, wherein the first part extends along the first outer edge portion, and the second part extends along the second outer edge portion, and
when a first region where the piezoelectric substrate, the first excitation electrode, and the second excitation electrode overlap with each other is defined as a high acoustic velocity region, a second region where the piezoelectric substrate, the first excitation electrode, and the second excitation electrode overlap with the first part of the mass-adding film is defined as a first low acoustic velocity region, and a third region where the piezoelectric substrate, the first excitation electrode, and the second excitation electrode overlap with the second part of the mass-adding film is defined as a second low acoustic velocity region, and
when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C:
A=C<B,
in the plan view, an outer edge portion of the first low acoustic velocity region opposite to the second low acoustic velocity region and an outer edge of the second low acoustic velocity region opposite to the first low acoustic velocity region overlap with the first excitation electrode, and
in the plan view, the third outer edge portion and the fourth outer edge portion of the second excitation electrode overlap with the first excitation electrode.

3. The piezoelectric vibration element according to claim 1, wherein in plan view, the first outer edge portion and the second outer edge portion overlap with the second excitation electrode.

4. The piezoelectric vibration element according to claim 1, wherein when a dimension in the first direction between an outer edge portion of the first low acoustic velocity region opposite to the central portion and an outer edge portion of the second low acoustic velocity region opposite to the central portion is defined as E, and a distance in the first direction between an outer edge portion proximal to the first low acoustic velocity region and an outer edge portion proximal to the second low acoustic velocity region in the high acoustic velocity region is defined as E′, a dimension of the first low acoustic velocity region in the first direction and a dimension of the second low acoustic velocity region in the first direction are (1+0.04)×(E−E′)/2.

5. The piezoelectric vibration element according to claim 1, wherein when a dimension in the first direction between an end portion of the first part opposite to the second part and an end portion of the second part opposite to the first part in the mass-adding film is defined as A, and a dimension of the first excitation electrode in the first direction is defined as B, A<B.

6. The piezoelectric vibration element according to claim 5, wherein when a dimension of the second excitation electrode in the first direction is defined as C, A<B<C.

7. The piezoelectric vibration element according to claim 5, wherein when a dimension of the second excitation electrode in the first direction is defined as C, A<B=C.

8. The piezoelectric vibration element according to claim 5, wherein when a dimension of the second excitation electrode in the first direction is defined as C, A=C<B.

9. The piezoelectric vibration element according to claim 5, wherein when a dimension of the second excitation electrode in the first direction is defined as C, A<C<B.

10. The piezoelectric vibration element according to claim 1, wherein when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C, A=B<C.

11. The piezoelectric vibration element according to claim 1, wherein when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C, B<A=C.

12. The piezoelectric vibration element according to claim 1, wherein when a dimension in the first direction between an end portion of the first part opposite to the second part and an end portion of the second part opposite to the first part in the mass-adding film is defined as A, a dimension of the first excitation electrode in the first direction is defined as B, and a dimension of the second excitation electrode in the first direction is defined as C, B<A<C.

13. The piezoelectric vibration element according to claim 1, wherein a material of the mass-adding film is an electric conductor.

14. The piezoelectric vibration element according to claim 1, wherein a material of the mass-adding film is an insulator.

15. The piezoelectric vibration element according to claim 1, wherein when a distance in the first direction between an end portion of the first part opposite to the second part and an end portion of the second part opposite to the first part in the mass-adding film is defined as A′, and a dimension of the first excitation electrode in the first direction is defined as B, A′/B≤0.5.

16. The piezoelectric vibration element according to claim 15, wherein 0.05≤A′/B.

17. The piezoelectric vibration element according to claim 1, wherein a distance in the first direction between an outer edge portion positioned on the first side of the first part of the mass-adding film and the first outer edge portion of the first excitation electrode, and a distance in the first direction between an outer edge portion positioned on the second side of the second part of the mass-adding film and the second outer edge portion of the first excitation electrode are 0.5 μm or greater.

18. The piezoelectric vibration element according to claim 17, wherein the distance in the first direction between the outer edge portion positioned on the first side of the first part of the mass-adding film and the first outer edge portion of the first excitation electrode, and the distance in the first direction between the outer edge portion positioned on the second side of the second part of the mass-adding film and the second outer edge portion of the first excitation electrode are 8 μm or less.

19. The piezoelectric vibration element according to claim 1, wherein when a dimension of the first excitation electrode in the first direction is defined as B, and a dimension of the second excitation electrode in the first direction is defined as C, 3 μm≤C−B.

20. The piezoelectric vibration element according to claim 19, wherein when the dimension of the first excitation electrode in the first direction is defined as B, and the dimension of the second excitation electrode in the first direction is defined as C, C−B≤8 μm.

21. The piezoelectric vibration element according to claim 1, wherein
the mass-adding film includes a third part and a fourth part which do not overlap the central portion of the first excitation electrode,
the first excitation electrode includes a fifth outer edge portion positioned on a third side in the second direction with respect to the central portion and a sixth outer edge portion positioned on a fourth side in the second direction with respect to the central portion, in the plan view,
the second excitation electrode includes a seventh outer edge portion positioned on the third side in the second direction with respect to the central portion and an eighth outer edge portion positioned on the fourth side in the second direction with respect to the central portion, in the plan view,
the third part extends along the fifth outer edge portion,
the fourth part extends along the sixth outer edge portion, and
when a fourth region where the piezoelectric substrate, the first excitation electrode, and the second excitation electrode overlap with the third part of the mass-adding film is defined as a third low acoustic velocity region, and a fifth region where the piezoelectric substrate, the first excitation electrode, and the second excitation electrode overlap with the fourth part of the mass-adding film is defined as a fourth low acoustic velocity region, in the plan view:
the seventh outer edge portion is farther from the central portion than the third low acoustic velocity region, and
the eighth outer edge portion is farther from the central portion than the fourth low acoustic velocity region.

22. The piezoelectric vibration element according to claim 1, wherein
the mass-adding film includes a third part and a fourth part which do not overlap the central portion of the first excitation electrode,
the first excitation electrode includes a fifth outer edge portion on a third side in the second direction with respect to the central portion and a sixth outer edge portion on a fourth side in the second direction with respect to the central portion, in the plan view,
the second excitation electrode includes a seventh outer edge portion on the third side in the second direction with respect to the central portion and an eighth outer edge portion on the fourth side in the second direction with respect to the central portion, in the plan view,
the third part extends along the fifth outer edge portion,
the fourth part extends along the sixth outer edge portion, and
a fourth region where the piezoelectric substrate, the first excitation electrode, and the second excitation electrode overlap with the third part of the mass-adding film is defined as a third low acoustic velocity region, and a fifth region where the piezoelectric substrate, the first excitation electrode, and the second excitation electrode further overlap with the fourth part of the mass-adding film is defined as a fourth low acoustic velocity region,
a dimension in the second direction between an end portion of the third part opposite to the fourth part and an end portion of the fourth part opposite to the third part in the mass-adding film is equal to a dimension of the second excitation electrode in the second direction and is smaller than a dimension of the first excitation electrode in the second direction,
in the plan view, an outer edge portion of the third low acoustic velocity region opposite to the fourth low acoustic velocity region and an outer edge portion of the fourth low acoustic velocity region opposite to the third low acoustic velocity region overlap with the first excitation electrode, and
in the plan view, the seventh outer edge portion and the eighth outer edge portion of the second excitation electrode overlap with the first excitation electrode.

23. The piezoelectric vibration element according to claim 1, wherein
the first excitation electrode includes a fifth outer edge portion positioned on a third side in the second direction with respect to the central portion and a sixth outer edge portion positioned on a fourth side in the second direction with respect to the central portion, in the plan view, and
in the plan view, the fifth outer edge portion and the sixth outer edge portion overlap with the second excitation electrode.

24. The piezoelectric vibration element according to claim 1, wherein the piezoelectric substrate is a quartz crystal element.

25. The piezoelectric vibration element according to claim 24, wherein cut-angles of the quartz crystal element is an AT cut, a BT cut, or an ST cut.

26. The piezoelectric vibration element according to claim 1, wherein a main vibration mode of the piezoelectric vibration element is a thickness shear vibration.
